(19) United States
(12) Patent Application Publication
(10) Pub. No.: US 2026/0140151 A1
(43) Pub. Date: May 21, 2026

(54) SYSTEM AND METHOD FOR ELECTRICAL SAFETY MONITORING IN AQUATIC ENVIRONMENTS

(71) Applicant: Shock Tracker LLC, Alpharetta, GA (US)

(72) Inventors: Andrey Karnauch, Alpharetta, GA (US); Yevhen Dobrenko, Alpharetta, GA (US); Sergey Mikhaylov, Alpharetta, GA (US); Aleksandr Tsynman, Alpharetta, GA (US)

(21) Appl. No.: 19/384,523

(22) Filed: Nov. 10, 2025

Related U.S. Application Data
(60) Provisional application No. 63/722,434, filed on Nov. 19, 2024.

(51) Int. Cl. G01R 19/165; G01N 27/07; G01R 19/12; G08B 7/06; G08B 21/18; G08B 25/01; G08B 29/18; G08B 31/00

(52) U.S. Cl. CPC G01R 19/16533; G01N 27/07; G01R 19/12; G08B 7/06; G08B 21/182; G08B 21/185; G08B 25/018; G08B 29/181; G08B 31/00

(57) ABSTRACT

A system for detecting electrical current in water includes a controller board and at least one sensor board communicatively coupled thereto. The controller may include a microcontroller configured to process signals, a display to show status information, at least one light-emitting diode to generate visual alerts, a siren for audible alerts, at least one button for user input, and a communication module to transmit data to a remote server. Each sensor board may include a tetrahedral electrode assembly configured for submersion in water to measure electrical current in three-dimensional space, a sensor microcontroller for processing measurements and generating wake-up signals, and galvanic isolation circuitry. A power management system may manage power from grid, solar, and battery sources, and a cable system may provide power and communication between the controller and sensor board.

### RELATED APPLICATION

Under provisions of 35 U.S.C. § 119(e), the Applicant claims benefit of U.S. Provisional Application No. 63/722,434 filed on Nov. 19, 2024, and having inventors in common, which is incorporated herein by reference in its entirety.

It is intended that the referenced application may be applicable to the concepts and embodiments disclosed herein, even if such concepts and embodiments are disclosed in the referenced application with different limitations and configurations and described using different examples and terminology.

### FIELD OF DISCLOSURE

The present disclosure generally relates to electrical safety monitoring systems for aquatic environments. More specifically, the disclosure pertains to distributed sensor networks for detecting electrical current in water bodies using multi-electrode sensor assemblies with separated controller and sensor board architectures.

### BACKGROUND

In some situations, electrical current may leak into water bodies around docks and marinas from faulty electrical systems. For example, damaged shore power connections, corroded wiring, or improperly grounded electrical equipment can introduce dangerous electrical current into the water. Thus, the conventional strategy is to rely on ground fault circuit interrupters at electrical panels and basic two-electrode conductivity measurements. This often causes problems because the conventional strategy does not provide real-time monitoring of electrical current already present in the water. For example, GFCIs only protect at the electrical source and cannot detect current that has already entered the water from multiple potential sources.

Conventional water electrical safety systems primarily utilize ground fault circuit interrupters installed at electrical distribution panels. These devices monitor electrical current flow and disconnect power when an imbalance is detected. However, GFCIs cannot detect electrical current that has already leaked into the water from various sources throughout a marina or dock facility.

Traditional current detection systems employ simple two-electrode configurations for measuring electrical conductivity in water. These systems suffer from galvanic interference effects that produce false readings. The galvanic effects occur when dissimilar metals in seawater create electrochemical reactions that generate spurious electrical signals.

Existing monitoring systems rely on centralized architectures with analog signal transmission over long cable runs. Signal degradation occurs as analog signals travel through extended cable lengths. This degradation limits the placement of sensors and reduces measurement accuracy in large aquatic installations.

Current water safety devices require continuous grid power for operation. This power dependency limits deployment flexibility in remote marine locations. Battery backup systems in conventional devices provide only short-term operation during power outages.

Conventional two-electrode measurement systems produce unreliable readings due to electrochemical interference between dissimilar metals submerged in conductive water. The electrochemical reactions generate voltage potentials that mask actual electrical current measurements. These galvanic effects vary unpredictably with water temperature and salinity conditions.

Traditional monitoring architectures employ analog signal transmission over extended cable distances in marine installations. Signal attenuation occurs as electrical signals propagate through long transmission lines. Electromagnetic interference from nearby electrical equipment further degrades measurement accuracy.

Existing safety systems cannot distinguish between alternating current and direct current leakage into water bodies. Different current types require distinct detection methodologies for accurate measurement. Many electrical faults produce direct current leakage that remains undetected by alternating current monitoring systems.

Current detection devices lack spatial resolution for determining electrical current distribution patterns in three-dimensional water volumes. Single-point measurements cannot identify current flow direction or intensity gradients. This limitation prevents accurate assessment of hazard zones around electrical leakage sources.

Conventional systems require manual threshold adjustment for different water conductivity conditions. Salinity variations between fresh water and seawater significantly affect electrical measurement sensitivity. Fixed detection thresholds produce false alarms in high-conductivity environments or missed detections in low-conductivity conditions.

Existing marine electrical safety equipment depends on continuous shore power for operation. Power interruptions disable monitoring capabilities during electrical storms when hazards are most likely to occur. Remote marine locations often lack reliable electrical infrastructure for powering safety monitoring systems.

Traditional water safety devices provide only local alarm capabilities without remote notification features. Personnel may not be present at monitoring locations when electrical hazards develop. Delayed hazard detection increases exposure time for individuals entering contaminated water areas.

Therefore, there is a need for an electrical safety monitoring solution that can detect electrical current already present in water bodies from multiple sources, provide three-dimensional spatial analysis of current distribution patterns, operate reliably in varying water conductivity conditions, and function independently of continuous shore power while offering remote monitoring capabilities for personnel safety in marine environments.

### BRIEF OVERVIEW

This brief overview is provided to introduce a selection of concepts in a simplified form that are further described below in the Detailed Description. This brief overview is not intended to identify key features or essential features of the claimed subject matter. Nor is this brief overview intended to be used to limit the claimed subject matter's scope.

A water current detection system may comprise a controller board, at least one sensor board, a power management system, and a cable system. The controller board may comprise a microcontroller configured to process digital signals. The controller board may comprise a display configured to show status information. The controller board may comprise at least one light-emitting diode configured to generate visual alerts. The controller board may comprise a siren configured to generate audible alerts. The controller board may comprise at least one button configured to receive user input. The controller board may comprise a communication module configured to transmit data to a remote server.

The at least one sensor board may be communicatively coupled to the controller board. The at least one sensor board may comprise a tetrahedral electrode assembly configured to be submerged in water and measure electrical current in three-dimensional space. The at least one sensor board may comprise a sensor microcontroller configured to process local measurements and generate wake-up signals. The at least one sensor board may comprise galvanic isolation circuitry configured to isolate the tetrahedral electrode assembly from the controller board power supply. The power management system may be configured to manage power from multiple sources comprising grid power, solar power, and battery power. The cable system may be configured to provide both power and communication between the controller board and the at least one sensor board.

A method for detecting electrical current in water using a modular water current detection system may comprise initializing communication between a controller board and at least one sensor board via a digital signal network. The method may comprise submerging a tetrahedral electrode assembly of the at least one sensor board in water. The method may comprise measuring electrical current between different combinations of three electrodes from the tetrahedral electrode assembly to determine three-dimensional current flow patterns. The method may comprise processing the measurements locally at the sensor board using a sensor microcontroller to detect absolute threshold breaches. The method may comprise transmitting wake-up signals from the sensor board to the controller board upon detecting threshold breaches. The method may comprise activating visual alerts using at least one light-emitting diode and audible alerts using a siren when dangerous current levels are detected. The method may comprise transmitting measurement data and alert information to a remote server via a communication module.

A device for detecting electrical current in water may comprise a floating housing configured to be deployed in water. The device may comprise a tetrahedral electrode assembly disposed on the floating housing and configured to measure electrical current in three-dimensional space when submerged. The device may comprise a microcontroller coupled to the tetrahedral electrode assembly and configured to measure electric currents between different combinations of three electrodes from the tetrahedral electrode assembly. The microcontroller may be configured to analyze the measured electric currents to determine three-dimensional current flow patterns. The microcontroller may be configured to determine whether the three-dimensional current flow patterns indicate electrical hazards. The microcontroller may be configured to generate alert signals when electrical hazards are detected. The device may comprise a GPS module coupled to the microcontroller and configured to determine geographic location of the device. The device may comprise an accelerometer and gyroscope coupled to the microcontroller and configured to detect orientation and movement of the device. The device may comprise at least one output component configured to provide visual and audible alerts based on the alert signals. The device may comprise a wireless communication module configured to transmit measurement data and location information to a remote monitoring system. The device may comprise a solar panel coupled to the floating housing and configured to charge a rechargeable battery, the rechargeable battery configured to power the microcontroller and associated components.

Both the foregoing brief overview and the following detailed description provide examples and are explanatory only. Accordingly, the foregoing brief overview and the following detailed description should not be considered to be restrictive. Further, features or variations may be provided in addition to those set forth herein. For example, embodiments may be directed to various feature combinations and sub-combinations described in the detailed description.

### BRIEF DESCRIPTION OF THE DRAWINGS

The accompanying drawings, which are incorporated in and constitute a part of this disclosure, illustrate various embodiments of the present disclosure. The drawings contain representations of various trademarks and copyrights owned by the Applicant. In addition, the drawings may contain other marks owned by third parties and are being used for illustrative purposes only. All rights to various trademarks and copyrights represented herein, except those belonging to their respective owners, are vested in and the property of the Applicant. The Applicant retains and reserves all rights in its trademarks and copyrights included herein, and grants permission to reproduce the material only in connection with reproduction of the granted patent and for no other purpose.

Furthermore, the drawings may contain text or captions that may explain certain embodiments of the present disclosure. This text is included for illustrative, non-limiting, explanatory purposes of certain embodiments detailed in the present disclosure. In the drawings:

FIG. 1A illustrates a system architecture diagram showing the overall water current detection system with sensor modules, control module, external server with cloud connectivity, and external data storage with bidirectional communication paths;

FIG. 1B illustrates a block diagram of a sensor module showing internal components including communication interface, sensor microcontroller, environmental sensors, galvanic isolation circuitry, and electrical current sensor with a tetrahedral electrode assembly;

FIG. 1C illustrates a block diagram of a control module showing the microcontroller, visual alert components, siren, display, navigation buttons, communication module, ground fault control interruption circuit, and power management system;

FIG. 2A illustrates an example embodiment of a plurality of sensor subassemblies, each having a tetrahedral electrode arrangement;

FIG. 2B illustrates a perspective view of an embodiment of the control device housing showing the front panel with display, indicators, and cable connections;

FIG. 2C illustrates a perspective view of an embodiment of a floating sensor device with a disc-shaped housing, solar panel, and cable connections;

FIG. 3A illustrates a daisy chain network configuration with a control module connected to multiple sensor modules in sequence;

FIG. 3B illustrates a star network configuration with a central control module connected to four peripheral sensor modules;

FIG. 3C illustrates a mixed network topology showing interconnected control and sensor modules with branching communication paths;

FIG. 4 illustrates a flowchart of the method for detecting electrical current in water using the sensor system, including initialization, measurement, threshold detection, and alert processes; and

FIG. 5 illustrates a block diagram of the computing device architecture showing the processor, memory, bus system, power supply, and various peripheral interfaces including sensors and communication modules.

### DETAILED DESCRIPTION

As a preliminary matter, it will readily be understood by one having ordinary skill in the relevant art that the present disclosure has broad utility and application. As should be understood, any embodiment may incorporate only one or a plurality of the above-disclosed aspects of the disclosure and may further incorporate only one or a plurality of the above-disclosed features. Furthermore, any embodiment discussed and identified as being “preferred” is considered to be part of a best mode contemplated for carrying out the embodiments of the present disclosure. Other embodiments also may be discussed for additional illustrative purposes in providing a full and enabling disclosure. Moreover, many embodiments, such as adaptations, variations, modifications, and equivalent arrangements, will be implicitly disclosed by the embodiments described herein and fall within the scope of the present disclosure.

Accordingly, while embodiments are described herein in detail in relation to one or more embodiments, it is to be understood that this disclosure is illustrative and exemplary of the present disclosure and are made merely to provide a full and enabling disclosure. The detailed disclosure herein of one or more embodiments is not intended, nor is to be construed, to limit the scope of patent protection afforded in any claim of a patent issuing here from, which scope is to be defined by the claims and the equivalents thereof. It is not intended that the scope of patent protection be defined by reading into any claim a limitation found herein that does not explicitly appear in the claim itself.

Thus, for example, any sequence(s) and/or temporal order of steps of various processes or methods that are described herein are illustrative and not restrictive. Accordingly, it should be understood that, although steps of various processes or methods may be shown and described as being in a sequence or temporal order, the steps of any such processes or methods are not limited to being carried out in any particular sequence or order, absent an indication otherwise. Indeed, the steps in such processes or methods generally may be carried out in various different sequences and orders while still falling within the scope of the present invention. Accordingly, it is intended that the scope of patent protection is to be defined by the issued claim(s) rather than the description set forth herein.

Additionally, it is important to note that each term used herein refers to that which an ordinary artisan would understand such a term to mean based on the contextual use of the term herein. To the extent that the meaning of a term used herein—as understood by the ordinary artisan based on the contextual use of such term—differs in any way from any particular dictionary definition of such term, it is intended that the meaning of the term as understood by the ordinary artisan should prevail.

Regarding applicability of 35 U.S.C. § 112, ¶6, no claim element is intended to be read in accordance with this statutory provision unless the explicit phrase “means for” or “step for” is actually used in such claim element, whereupon this statutory provision is intended to apply in the interpretation of such claim element.

Furthermore, it is important to note that, as used herein, “a” and “an” each generally denotes “at least one,” but does not exclude a plurality unless the contextual use dictates otherwise. When used herein to join a list of items, “or” denotes “at least one of the items,” but does not exclude a plurality of items of the list. Finally, when used herein to join a list of items, “and” denotes “all of the items of the list.”

The following detailed description refers to the accompanying drawings. Wherever possible, the same reference numbers are used in the drawings and the following description to refer to the same or similar elements. While many embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims. The present disclosure contains headers. It should be understood that these headers are used as references and are not to be construed as limiting upon the subject matter disclosed under the header.

The present disclosure addresses technical problems associated with electrical safety monitoring in aquatic environments where dangerous electrical currents may pose significant risks to human life and safety. Traditional electrical safety systems may suffer from several limitations that compromise their effectiveness in detecting and responding to electrical hazards in water.

Existing electrical current detection systems may lack the capability to accurately measure electrical currents in three-dimensional space around submerged objects or structures. Conventional two-dimensional measurement approaches may fail to detect current flow patterns that occur in complex three-dimensional water environments. This limitation may result in undetected electrical hazards that could pose serious safety risks to swimmers, divers, and marine personnel operating in the vicinity.

Current detection systems may also lack the ability to distinguish between actual electrical current leakage and environmental electrical noise that occurs naturally in aquatic environments. Environmental factors such as galvanic effects between dissimilar metals, electrochemical reactions, and naturally occurring electrical potentials may generate false positive readings that compromise the reliability of hazard detection systems. These false readings may lead to unnecessary alarm conditions or may cause operators to disable safety systems due to frequent nuisance alarms.

Traditional water safety monitoring systems may not provide adequate coverage for large aquatic areas such as marina complexes, industrial water facilities, or extended dock structures. Single-point measurement systems may fail to detect electrical hazards that occur at locations distant from the monitoring device. This coverage limitation may leave significant portions of an aquatic facility unprotected from electrical hazards.

Existing electrical safety systems may lack the capability to automatically adjust detection thresholds based on changing water conditions. Water salinity levels may vary significantly between fresh water and salt water environments, and may also change over time due to environmental factors. Detection systems that cannot compensate for these salinity variations may produce inaccurate measurements or may fail to detect hazardous conditions when water conductivity changes.

Power management represents another significant challenge in aquatic electrical safety monitoring systems. Many existing systems may require continuous connection to grid power sources, which may not be available in remote marine locations or may be unreliable due to weather conditions. Battery-powered systems may have limited operational life and may require frequent maintenance to replace discharged batteries.

Communication and remote monitoring capabilities may be inadequate in traditional electrical safety systems. Local alarm systems may not provide sufficient warning to personnel who are not in the immediate vicinity of the monitoring device. The absence of remote monitoring capabilities may prevent facility operators from receiving timely notifications of electrical hazard conditions.

Grid power monitoring and safety response capabilities may be insufficient in existing systems. Electrical hazards in water may originate from faulty shore power connections, damaged underwater electrical equipment, or ground fault conditions in marina electrical systems. Systems that cannot monitor grid power quality or automatically disconnect faulty electrical sources may fail to eliminate the source of electrical hazards in water.

The present system addresses these technical problems through a distributed monitoring architecture comprising a controller board and one or more sensor boards connected via a digital communication network. The controller board may serve as the central processing and coordination unit, while sensor boards may provide localized current measurement capabilities using tetrahedral electrode assemblies positioned at strategic locations throughout the monitored aquatic area.

The tetrahedral electrode configuration enables three-dimensional measurement of electrical current flow patterns in water. Each sensor board may utilize four electrodes positioned at the vertices of a tetrahedron to create multiple measurement planes. The sensor board may sequentially measure electrical current between different combinations of three electrodes to construct a comprehensive three-dimensional current flow pattern around the sensor location.

Galvanic isolation circuitry within each sensor board may separate the electrode measurement circuits from the main power supply system. This isolation may prevent ground loop interference and may enable accurate current measurements even when multiple sensor boards are connected to a common controller board. The galvanic isolation may also enhance system safety by preventing electrical current from the measurement circuits from affecting the main system electronics.

Digital signal processing algorithms implemented in both the sensor board microcontrollers and the controller board may filter environmental electrical noise and distinguish actual current leakage from galvanic effects. The system may apply multiple signal processing techniques including differential calculations, threshold detection, and pattern recognition to improve measurement accuracy and reduce false alarm conditions.

Multiple sensor boards connected to a single controller board may provide extended coverage for large aquatic areas. The controller board may coordinate measurements from multiple sensor locations and may correlate data between sensor boards to detect electrical hazards that span multiple measurement points. This distributed measurement approach may provide comprehensive monitoring coverage for complex aquatic facilities.

Self-calibration capabilities based on water temperature and salinity measurements may enable the system to automatically adjust detection thresholds for varying water conditions. Each sensor board may include temperature sensors embedded within the tetrahedral electrode assembly to measure local water conditions. The system may apply correction factors based on these measurements to maintain accurate current detection across different water environments.

Power management systems may support multiple power sources including grid power, solar power, and battery backup. The controller board may automatically switch between available power sources based on power quality and availability. Solar panels may provide sustainable power generation for extended autonomous operation in remote locations where grid power is not available.

Grid power monitoring capabilities may enable the controller board to detect fault conditions including ground voltage presence, voltage imbalance, undervoltage, and overvoltage conditions. When dangerous current levels are detected in the water, the system may automatically trip ground fault circuit interrupters to disconnect the electrical source causing the hazard.

Wireless communication modules may provide real-time data transmission to cloud-based monitoring systems. The controller board may transmit measurement data, system status information, and alarm conditions to remote servers for centralized monitoring and analysis. Mobile applications and web-based dashboards may provide facility operators with immediate access to system status and hazard notifications.

Wake-up signaling capabilities may enable power-efficient operation while maintaining rapid response to hazard conditions. Sensor board microcontrollers may continuously monitor for threshold breach conditions and may transmit wake-up signals to the controller board when hazardous conditions are detected. This approach may significantly reduce power consumption while ensuring immediate system response to electrical hazards.

The system architecture may support both permanent dock-mounted installations and temporary floating deployments. Dock-mounted systems may utilize ruggedized cables (e.g., CAT8 cables) to connect multiple sensor boards to a centrally located controller board. Floating systems may integrate controller board and sensor board functionality into a single waterproof housing with GPS positioning and solar power capabilities for autonomous operation.

The disclosed solution addresses the technical challenges in electrical safety monitoring for aquatic environments through a comprehensive multi-component architecture that may enable precise three-dimensional current detection, automated safety responses, and distributed monitoring capabilities.

The system may comprise a controller board that functions as the central coordination unit for electrical safety monitoring operations. The controller board may include a microcontroller configured to process measurement data from multiple sensor locations and coordinate system-wide safety responses. The controller board may further include a display configured to present status information for each connected sensor board, grid power conditions, and system operational parameters. Visual alert components may comprise light-emitting diodes configured to provide immediate hazard notifications through programmable color patterns and brightness levels. An audible alert system may include a siren configured to generate high-intensity sound alerts when dangerous current conditions are detected in the monitored water area.

The controller board may incorporate user interface elements including buttons configured to enable local navigation through system status displays and configuration menus. A communication module may be integrated within the controller board to provide wireless connectivity for data transmission to cloud-based monitoring systems and mobile applications. The communication module may support multiple wireless protocols including cellular and Wi-Fi connectivity to ensure reliable data transmission across various deployment environments.

Power management capabilities within the controller board may enable operation from multiple power sources including grid power, solar power, and internal battery backup. The power management system may automatically monitor grid voltage conditions and detect fault conditions such as ground voltage presence, voltage imbalance, undervoltage, and overvoltage conditions. When dangerous current levels are detected in the water, the controller board may automatically trigger ground fault circuit interrupter mechanisms to disconnect electrical sources that may be contributing to the hazardous condition.

The system may include one or more sensor boards that may be communicatively coupled to the controller board through a digital communication network. Each sensor board may comprise a tetrahedral electrode assembly configured for submersion in water to enable three-dimensional electrical current measurement capabilities. The tetrahedral configuration may position four electrodes at the vertices of a tetrahedron to create multiple measurement planes for comprehensive current flow analysis.

Each sensor board may include a sensor microcontroller configured to perform local measurement processing and generate wake-up signals to the controller board when threshold breach conditions are detected. The sensor microcontroller may execute local signal processing algorithms including minimum and maximum value calculations, threshold detection, and rate of change analysis to predict hazardous conditions before critical thresholds are exceeded.

Galvanic isolation circuitry within each sensor board may separate the tetrahedral electrode assembly from the controller board power supply system. This isolation may prevent ground loop interference and enable accurate current measurements when multiple sensor boards are connected to a common controller board. The galvanic isolation may enhance system safety by preventing electrical current from the measurement circuits from affecting the main system electronics.

Temperature sensors may be embedded within the tetrahedral electrode assembly to measure local water conditions and enable automatic calibration adjustments. The system may apply correction factors based on temperature measurements to maintain accurate current detection across varying water environments and seasonal conditions.

The cable system may comprise ruggedized cables configured to provide both power delivery and digital communication between the controller board and multiple sensor boards. As non-limiting examples, the cables may be CAT8 cables or other shielded twisted-pair cables. The cable system may support daisy-chain or star network topologies to enable flexible deployment configurations for different aquatic facility layouts. Each sensor board may be configured to operate independently when data communication with the controller board is unstable or interrupted, and store local measurement data for transmission when connectivity is restored.

The system may support both permanent dock-mounted installations and temporary floating deployments depending on the specific monitoring requirements. Dock-mounted systems may utilize the ruggedized cable infrastructure to connect multiple sensor boards to a centrally located controller board for comprehensive area coverage. Floating systems may integrate controller board and sensor board functionality into a single waterproof housing with GPS positioning capabilities and solar power systems for autonomous operation.

Wake-up signaling capabilities may enable power-efficient operation while maintaining rapid response to hazardous conditions. The sensor board microcontrollers may continuously monitor for absolute threshold breaches and transmit wake-up signals to the controller board when dangerous conditions are detected. This approach may significantly reduce overall system power consumption while ensuring immediate response to electrical hazards.

Ground connection capabilities at each sensor board may enable enhanced measurement modes when multiple sensor boards are deployed. The system may coordinate ground loop potential measurements between sensor boards and utilize temporary ground connections for improved measurement accuracy when safe ground loop conditions are verified.

Digital signal processing algorithms may be implemented throughout the system to distinguish actual current leakage from environmental electrical noise and galvanic effects. The system may apply differential calculations, pattern recognition, and multiple filtering techniques to improve measurement reliability and reduce false alarm conditions.

The system may provide extended coverage for large aquatic areas through coordinated measurements from multiple sensor locations. The controller board may correlate data between sensor boards to detect electrical hazards that span multiple measurement points and provide comprehensive monitoring coverage for complex marina facilities and industrial water installations.

The controller board may implement data fusion algorithms that combine measurement data from multiple sensor boards to detect hazard events that span several monitoring locations. For example, the controller may perform spatial and temporal correlation of current measurements, comparing concurrent readings from various sensor nodes to identify distributed electrical hazards (e.g., stray current gradients, leakage paths crossing multiple sensors). The system may apply voting or consensus logic to minimize false alarms from transient noise at individual sensors, and may assign hazard severity scores based on the magnitude and geographic spread of detected current anomalies. In advanced embodiments, the controller board or remote analytics server may utilize pattern recognition and statistical clustering algorithms to identify persistent hazard sources and classify types of events based on historical measurement patterns.

In some embodiments, the system may comprise a fleet intelligence layer configured to aggregate measurement data from a plurality of distributed monitoring devices across multiple aquatic environments. The aggregated data may be analyzed using machine learning algorithms to identify hazardous trends, generate predictive risk maps for regions of interest, and initiate adaptive alerts. The fleet intelligence layer may continuously update hazard profiles for monitored areas based on device-reported measurements and remotely sensed environmental conditions, thereby enabling preemptive safety actions and dynamic adjustment of monitoring criteria for specific facilities or zones.

Cloud-based analytics platforms may aggregate raw and processed data from distributed monitoring systems to enable advanced predictive operations. Uploaded measurement histories, event records, and device health logs may be used to train machine learning models—such as time series classifiers, event predictors, and anomaly detectors—that can forecast risk periods, optimize alert thresholds, and predict maintenance needs. These models may automatically update risk maps for monitored locations, provide tailored device configuration recommendations, and issue proactive warnings to operators regarding emerging electrical hazard conditions or impending component failures.

The fleet intelligence layer may utilize machine learning models to analyze aggregate event data from multiple deployed devices, adaptively adjust detection thresholds based on emerging regional trends, and deliver predictive alerts to operators. This remote data aggregation enables fleet-wide anomaly detection, risk scoring, and early warning of potential hazards.

The present disclosure includes many aspects and features. Moreover, while many aspects and features relate to, and are described in, the context of a platform for detecting electrical current in water, embodiments of the present disclosure are not limited to use only in this context.

### I. Platform Overview

This overview is provided to introduce a selection of concepts in a simplified form that are further described below. This overview is not intended to identify key features or essential features of the claimed subject matter. Nor is this overview intended to be used to limit the claimed subject matter's scope.

The system addresses the need for comprehensive electrical safety monitoring in aquatic environments through an integrated platform that may detect dangerous electrical currents before they pose risks to human safety. The platform may comprise multiple components working together to provide real-time monitoring, automated safety responses, and remote management capabilities across various water environments including swimming pools, marinas, industrial facilities, and natural bodies of water.

The platform may operate through a distributed architecture that enables both temporary and permanent monitoring deployments. A floating device configuration may integrate all monitoring components into a single waterproof housing suitable for temporary deployment from boats or as anchored monitoring buoys. This floating configuration may include solar power generation, GPS positioning, and wireless communication capabilities to enable autonomous operation in remote locations where grid power may not be available.

A permanent dock-mounted configuration may provide enhanced monitoring coverage through a network of distributed sensors connected to a centralized control unit. The controller board may serve as the main coordination device, managing power distribution, data processing, and communication functions while remaining accessible for user interaction at dock locations. Multiple sensor boards may be positioned strategically throughout the monitored area to provide comprehensive coverage of large aquatic facilities.

Each sensor board may utilize a tetrahedral electrode assembly that enables three-dimensional measurement of electrical current flow patterns in water. This geometric configuration may allow the system to detect not only the presence of electrical current but also its direction and intensity across multiple measurement planes. The system may cycle through different combinations of three electrodes to construct a complete picture of the electrical environment surrounding each sensor location.

The platform may automatically adjust detection parameters based on environmental conditions that affect water conductivity. Temperature sensors embedded within the electrode assemblies may provide real-time measurements that enable the system to apply appropriate correction factors for varying water conditions. Salinity measurements may further enhance calibration accuracy by accounting for the significant conductivity differences between fresh water and salt water environments.

Power management capabilities may enable the system to operate from multiple sources including grid power, solar charging, and internal battery backup. The controller board may automatically monitor grid power quality and detect fault conditions such as voltage imbalances or ground faults that may contribute to electrical hazards in water. When dangerous current levels are detected, the system may automatically trigger ground fault circuit interrupter mechanisms to disconnect electrical sources that may be causing the hazard.

Communication systems may provide real-time data transmission to cloud-based monitoring platforms that enable remote oversight of multiple installations. Mobile applications and web-based dashboards may allow facility operators to monitor system status, receive immediate hazard notifications, and access historical data for trend analysis. The communication architecture may support multiple wireless protocols to ensure reliable connectivity across various deployment environments.

Alert systems may provide immediate local warnings through multiple modalities including high-intensity audio alarms, bright visual indicators, and electronic messaging to mobile devices. The system may generate different alert patterns based on the severity and type of electrical hazard detected, enabling appropriate responses from personnel in the vicinity of the monitored area.

Additional embodiments may enable the system to provide alerts via integration with facility emergency broadcast systems, automated voice announcements, SMS, e-mail, or push notifications through dedicated mobile applications. The alert engine may support programmable notification protocols to escalate warnings to on-site personnel, remote administrators, or emergency responders. Integration with third-party safety management platforms may provide broadened event visibility and rapid coordinated response to hazard conditions.

Notification protocols may include SMS text messages, email, app-based push notifications, automated voice calls, or integration with on-site emergency public address systems. The system may support programmable hierarchies such that different event classes trigger designated recipients or safety teams based on event severity, time-of-day, or operational context. Notification messages may include location, event time, hazard details, and recommended actions for recipient response.

The alert engine may be configured to accept trigger commands from remote monitoring platforms, cloud-based interfaces, or administrative users, enabling the audible and visual alert systems to be activated independently of local sensor detection. This capability supports safety drills, facility evacuations, and non-electrical emergency scenarios. The alert system may further provide integration points for third-party building management or public safety platforms, including support for standardized control protocols, to enable automated escalation and coordinated response during multi-system events.

Digital signal processing algorithms may distinguish actual electrical current leakage from environmental electrical noise and galvanic effects that occur naturally in aquatic environments. Multiple filtering techniques and pattern recognition methods may improve measurement reliability while reducing false alarm conditions that could compromise system effectiveness.

The modular system architecture may support flexible deployment configurations ranging from single-sensor installations to complex networks covering extensive marina facilities. Sensor boards may operate independently when data communication with the controller board is interrupted or unstable, storing local measurement data for transmission when connectivity is restored. This capability may ensure continuous monitoring even during communication interruptions or maintenance activities.

Ground connection capabilities at sensor locations may enable enhanced measurement modes when multiple sensors are deployed. The system may coordinate ground loop potential measurements between sensor boards and utilize temporary ground connections for improved measurement accuracy when safe ground loop conditions are verified through systematic analysis.

Wake-up signaling between sensor boards and the controller board may enable power-efficient operation while maintaining rapid response to hazardous conditions. Sensor board microcontrollers may continuously monitor for absolute threshold breaches and transmit immediate wake-up signals to activate full system response when dangerous conditions are detected.

The platform may provide extended operational life through sustainable power management that combines solar charging with battery backup systems. power delivery ports (e.g., USB ports) may enable external charging and power bank functionality for additional flexibility in various deployment scenarios.

Environmental monitoring capabilities may extend beyond electrical current detection to include water temperature, device orientation, humidity levels, and GPS positioning. This comprehensive sensor suite may provide valuable context for electrical measurements and enable more sophisticated analysis of conditions that may affect electrical safety in aquatic environments.

Embodiments of the present disclosure may comprise methods, systems, and a computer readable medium comprising, but not limited to, at least one of the following:
A. At least one Sensor Board;
B. A Controller Board;
C. A Power Management System;
D. A Cable System;

In some embodiments, the present disclosure may provide an additional set of modules for further facilitating the software and hardware platform. The additional set of modules may comprise, but not be limited to:
E. A Housing; and
F. A Power Source.

Details with regards to each module are provided below. Although modules are disclosed with specific functionality, it should be understood that functionality may be shared between modules, with some functions split between modules, while other functions duplicated by the modules. Furthermore, the name of each module should not be construed as limiting upon the functionality of the module. Moreover, each component disclosed within each module can be considered independently, without the context of the other components within the same module or different modules. Each component may contain functionality defined in other portions of this specification. Each component disclosed for one module may be mixed with the functionality of other modules. In the present disclosure, each component can be claimed on its own and/or interchangeably with other components of other modules.

The following depicts an example of a method of a plurality of methods that may be performed by at least one of the aforementioned modules, or components thereof. Various hardware components may be used at the various stages of the operations disclosed with reference to each module. For example, although methods may be described to be performed by a single computing device, it should be understood that, in some embodiments, different operations may be performed by different networked elements in operative communication with the computing device. For example, at least one computing device 500 may be employed in the performance of some or all of the stages disclosed with regard to the methods. Similarly, an apparatus may be employed in the performance of some or all of the stages of the methods. As such, the apparatus may comprise at least those architectural components as found in computing device 500.

Furthermore, although the stages of the following example method are disclosed in a particular order, it should be understood that the order is disclosed for illustrative purposes only. Stages may be combined, separated, reordered, and various intermediary stages may exist. Accordingly, it should be understood that the various stages, in various embodiments, may be performed in orders that differ from the ones disclosed below. Moreover, various stages may be added or removed without altering or departing from the fundamental scope of the depicted methods and systems disclosed herein.

Consistent with embodiments of the present disclosure, a method may be performed by at least one of the modules disclosed herein. The method may be embodied as, for example, but not limited to, computer instructions which, when executed, perform the method. The method may comprise the following stages:
initializing communication between a controller board and at least one sensor board via a digital signal network;
submerging a tetrahedral electrode assembly of the at least one
sensor board in water;

measuring electrical current between different combinations of three electrodes from the tetrahedral electrode assembly to determine three-dimensional current flow patterns;

processing the measurements locally at the sensor board using a sensor microcontroller to detect absolute threshold breaches;

transmitting wake-up signals from the sensor board to the controller board upon detecting threshold breaches;

activating visual alerts using at least one light-emitting diode and audible alerts using a siren when dangerous current levels are detected; and
transmitting measurement data and alert information to a remote server via a communication module.

Although the aforementioned method has been described to be performed by a platform 100 for detecting electrical current in water, it should be understood that computing device 500 may be used to perform the various stages of the method. Furthermore, in some embodiments, different operations may be performed by different networked elements in operative communication with computing device 500. For example, a plurality of computing devices may be employed in the performance of some or all of the stages in the aforementioned method. Moreover, a plurality of computing devices may be configured much like a single computing device 500. Similarly, an apparatus may be employed in the performance of some or all stages in the method. The apparatus may also be configured much like computing device 500.

Both the foregoing overview and the following detailed description provide examples and are explanatory only. Accordingly, the foregoing overview and the following detailed description should not be considered to be restrictive. Further, features or variations may be provided in addition to those set forth herein. For example, embodiments may be directed to various feature combinations and sub-combinations described in the detailed description.

### II. Platform Configuration

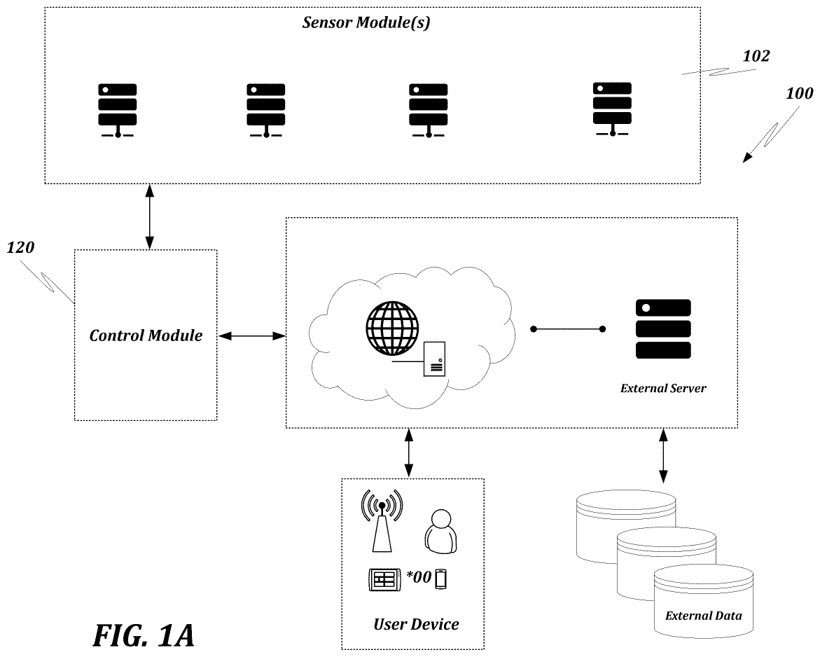

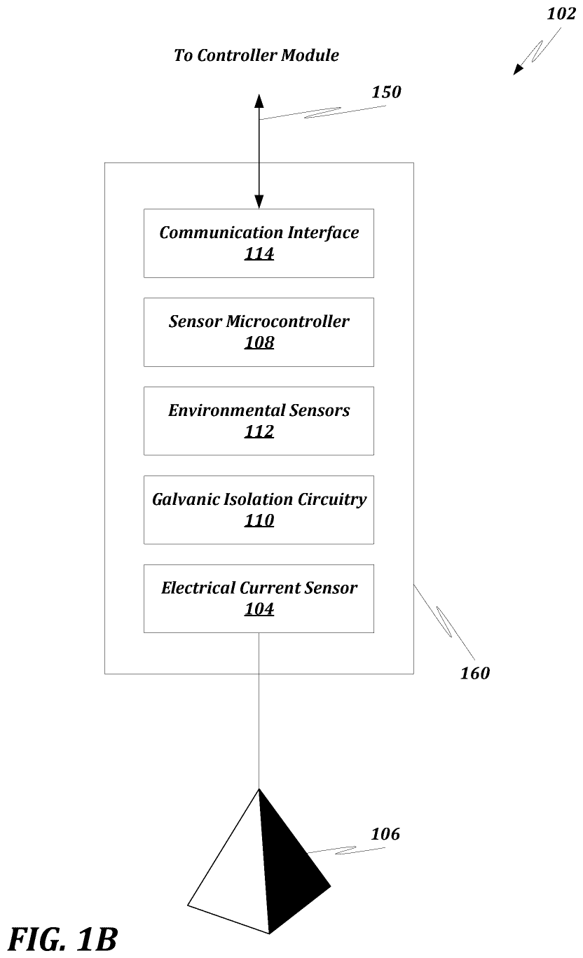

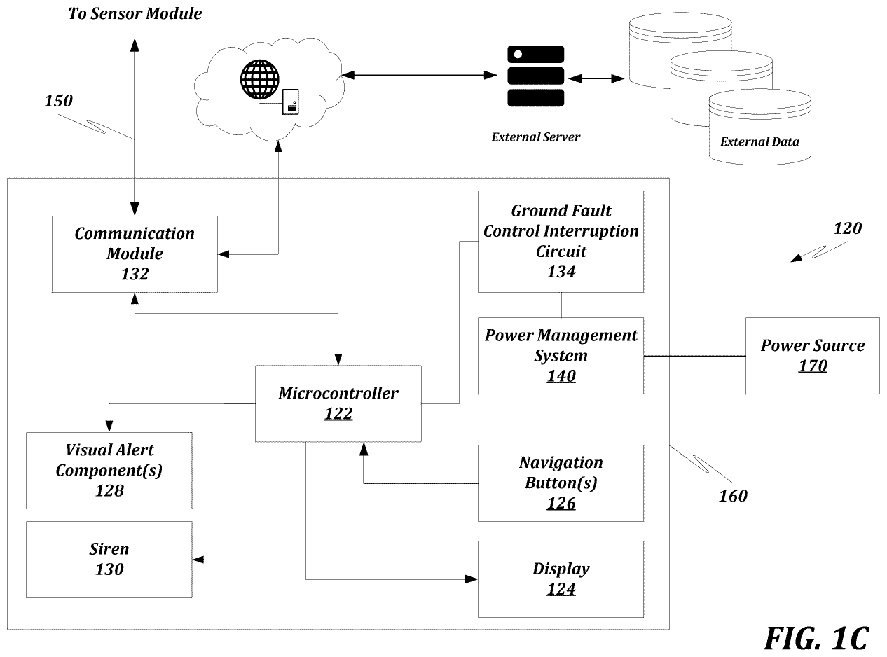

FIG. 1A1 illustrates one possible operating environment through which a platform consistent with embodiments of the present disclosure may be provided. By way of non-limiting example, a platform 100 for detecting electrical current in water may be hosted on, for example, a cloud computing service. In some embodiments, the platform 100 may be hosted on a computing device 500. A user may access platform 100 through a software application and/or hardware device. The software application may be embodied as, for example, but not be limited to, a website, a web application, a desktop application, and a mobile application compatible with the computing device 500.

The platform may enable comprehensive monitoring of electrical hazards across diverse aquatic environments through advanced three-dimensional current detection capabilities. The system may provide real-time hazard identification, automated safety responses, and centralized monitoring capabilities that may significantly enhance electrical safety standards in marine and freshwater applications.

The distributed architecture may comprise multiple sensor boards positioned strategically throughout monitored areas to provide comprehensive coverage of electrical conditions. Each sensor board may operate independently while maintaining communication with the central controller board through digital signal networks. This distributed approach may enable monitoring of large aquatic facilities such as marina complexes, industrial water treatment plants, and extended dock structures that may require coverage across significant distances.

The tetrahedral electrode configuration may enable precise measurement of electrical current flow in three-dimensional space around each sensor location. The system may sequentially measure electrical current between different combinations of three electrodes to construct comprehensive current flow patterns. This three-dimensional measurement capability may provide superior hazard detection compared to traditional two-dimensional approaches that may fail to detect current flow patterns occurring in complex aquatic environments.

Galvanic isolation circuitry within each sensor board may separate electrode measurement circuits from the main power supply system. This isolation may prevent ground loop interference that could compromise measurement accuracy when multiple sensor boards are connected to a common controller board. The galvanic isolation may also enhance system safety by preventing electrical current from measurement circuits from affecting main system electronics.

The controller board may serve as the central coordination unit for the entire monitoring system. The controller board may process measurement data from multiple sensor locations and coordinate system-wide safety responses. The controller board may include display capabilities to present status information for each connected sensor board, grid power conditions, and overall system operational parameters.

Power management capabilities may enable the system to operate from multiple power sources including grid power, solar power, and battery backup. The controller board may automatically monitor grid voltage conditions and detect fault conditions such as ground voltage presence, voltage imbalance, undervoltage, and overvoltage conditions. When dangerous current levels are detected in water, the controller board may automatically trigger ground fault circuit interrupter mechanisms to disconnect electrical sources that may be contributing to hazardous conditions.

Digital signal processing algorithms may be implemented throughout the system to distinguish actual current leakage from environmental electrical noise and galvanic effects. The system may apply multiple signal processing techniques including differential calculations, threshold detection, and pattern recognition to improve measurement accuracy and reduce false alarm conditions that could compromise system effectiveness.

Wake-up signaling capabilities may enable power-efficient operation while maintaining rapid response to hazardous conditions. Sensor board microcontrollers may continuously monitor for threshold breach conditions and may transmit wake-up signals to the controller board when dangerous conditions are detected. This approach may significantly reduce overall system power consumption while ensuring immediate system response to electrical hazards.

The cable system may comprise ruggedized cables (e.g., CAT8 cables or other shielded twisted-pair cables) configured to provide both power delivery and digital communication between the controller board and multiple sensor boards. The cable system may support daisy-chain or star network topologies to enable flexible deployment configurations for different aquatic facility layouts. Each sensor board may be configured to operate independently when data communication with the controller board is interrupted or unstable, and may store local measurement data for transmission when connectivity is restored.

Temperature sensors may be embedded within tetrahedral electrode assemblies to measure local water conditions and enable automatic calibration adjustments. The system may apply correction factors based on temperature measurements to maintain accurate current detection across varying water environments and seasonal conditions. Ground connection capabilities at each sensor board may enable enhanced measurement modes when multiple sensor boards are deployed.

Communication systems may provide real-time data transmission to cloud-based monitoring platforms that enable remote oversight of multiple installations. The communication architecture may support multiple wireless protocols to ensure reliable connectivity across various deployment environments. Mobile applications and web-based dashboards may allow facility operators to monitor system status, receive immediate hazard notifications, and access historical data for trend analysis.

In further embodiments, the platform may provide administrators with remote system access for device deployment, diagnostics, and lifecycle management. Users may remotely configure operational parameters, update detection thresholds, and initiate testing procedures using secure cloud-based dashboards or mobile applications. The system may facilitate over-the-air firmware upgrades, issue automated compliance reports, and schedule regular maintenance checks. A centralized interface may aggregate alerts from multiple facilities, supporting efficient large-scale management and providing compliance documentation for regulatory bodies or insurers.

Additionally, the platform may automate the compiling and transmission of compliance reports, system self-diagnostics, and event logs to designated regulatory authorities, insurers, or maintenance service providers. Scheduled reporting functions and secure electronic record-keeping may facilitate regulatory compliance and reduce administrative burdens for facility operators.

The system may support both permanent dock-mounted installations and temporary floating deployments depending on specific monitoring requirements. Dock-mounted systems may utilize the ruggedized cable infrastructure to connect multiple sensor boards to a centrally located controller board for comprehensive area coverage. Floating systems may integrate controller board and sensor board functionality into a single waterproof housing with GPS positioning capabilities and solar power systems for autonomous operation.

The system may further comprise a cable system configured to connect the controller board and sensor boards through a ruggedized communication network. The cable system may utilize cables (e.g., CAT8 cables or other shielded twisted-pair cables) that provide both power delivery and digital communication capabilities over extended distances. The cables may enable reliable data transmission between the controller board and multiple sensor boards while maintaining signal integrity across harsh marine environments.

The controller board may include a display configured to present status information for each connected sensor board. The display may show operational parameters including power source status, grid voltage conditions, and individual sensor board connectivity. Navigation buttons may be integrated within the controller board to enable local interface control and display menu navigation. The display may provide limited vital information while the primary system interface may be accessed through mobile applications and cloud-based portals.

The controller board may implement power management capabilities that support multiple power sources including grid power, solar power, and internal battery backup. The power management system may automatically prioritize power source selection based on availability and system requirements. Grid power monitoring may continuously assess voltage conditions and detect fault conditions including ground voltage presence, voltage imbalance, undervoltage, and overvoltage conditions. Grid data may be transmitted to cloud services for remote monitoring and analysis.

Battery backup may be integrated within the controller board to provide continuous operation during grid power interruptions. Solar panel connectivity may enable sustainable power generation for extended autonomous operation. The solar panel may be housed in a separate enclosure connected to the controller board for optimal solar exposure positioning.

Ground fault circuit interrupter capabilities may enable the controller board to automatically disconnect grid power when dangerous current levels are detected in water. The system may monitor ground loop potentials between multiple sensor boards and the controller board grid connection. This capability may enable enhanced measurement modes when multiple sensor boards are deployed with verified safe ground loop conditions.

Each sensor board may include a sensor microcontroller configured to perform local signal processing and communication protocol handling. The sensor microcontroller may execute minimum and maximum value calculations, cyclic redundancy check computations, and absolute threshold breach detection. Wake-up signaling capability may enable the sensor microcontroller to transmit immediate alerts to the controller board when measurement thresholds are exceeded.

The controller board may implement power-saving modes during low-activity periods to extend battery life. Wake-up signals from sensor board microcontrollers may enable rapid system activation when hazardous conditions are detected. This approach may significantly reduce overall power consumption while maintaining immediate response capability to electrical hazards.

Galvanic isolation circuitry within each sensor board may separate the tetrahedral electrode assembly from the controller board power supply system. This isolation may prevent ground loop interference and enable accurate current measurements when multiple sensor boards share a common power source. The galvanic isolation may enhance system safety by preventing electrical current from measurement circuits from affecting the main system electronics.

Power delivery to sensor boards may include short circuit protection and power monitoring capabilities. The controller board may monitor power consumption and operational status of each connected sensor board to ensure reliable system operation. Power and communication signals may be transmitted through the same cable infrastructure to simplify installation and reduce cable requirements.

The system may support both daisy-chain and star network topologies for connecting multiple sensor boards to a single controller board. Network topology selection may be based on deployment requirements and facility layout considerations. Digital signal networks may provide enhanced reliability over extended distances compared to analog signal transmission methods.

Temperature sensors may be embedded within tetrahedral electrode assemblies to enable water temperature monitoring and measurement calibration. Temperature data may be used to apply correction factors for varying water conditions and seasonal temperature changes. The sensor microcontroller may process temperature measurements locally and transmit calibrated current measurements to the controller board.

Ground connections at each sensor board location may enable additional measurement modes when multiple sensor boards are deployed. The system may coordinate ground loop potential measurements between sensor boards to verify safe operating conditions before enabling enhanced measurement capabilities. Temporary ground connections may be established between sensor boards when safe ground loop conditions are confirmed.

The system may implement multiple signal processing algorithms to distinguish actual current leakage from environmental electrical noise and galvanic effects. Differential calculation methods may be applied to detect current presence while filtering background electrical activity. Digital signal processing techniques may include noise reduction, pattern recognition, and threshold detection to improve measurement accuracy and reduce false alarm conditions.

Optional closed-circuit television camera integration may provide video monitoring capabilities for enhanced security and incident documentation. The camera system may be integrated within the controller board housing or deployed as a separate unit powered by the main system. Video streaming and local media storage capabilities may enable remote monitoring and incident recording.

The floating device configuration may integrate controller board and sensor board functionality into a single waterproof housing. Solar panel arrays may provide autonomous power generation for extended deployment without grid power access. GPS positioning and motion sensing capabilities may enable location tracking and orientation monitoring for floating deployments.

USB-C Power Delivery ports may provide external charging capabilities and power bank functionality for additional equipment. The floating device may include environmental sensors for comprehensive aquatic monitoring including humidity, temperature, and device orientation measurements.

In some implementations, a USB-C port or similar power delivery interface may be provided to output electrical power for external devices such as mobile phones or tablets. The device may function as a power bank, drawing from its internal battery or solar array, while continuing primary safety monitoring functions.

The system architecture may enable scalable deployment configurations ranging from single sensor installations to complex multi-sensor networks covering extensive aquatic facilities. Each sensor board may operate independently when data communication with the controller board is interrupted or unstable, and may store local measurement data for transmission when connectivity is restored.

Accordingly, as best shown in FIGS. 1A-3C, embodiments of the present disclosure provide a software and hardware platform comprised of a distributed set of computing elements, including, but not limited to:

### A. At Least One Sensor Board

The platform 100 may include at least one sensor sub-assembly or sensor board 102. As best shown in FIG. 1B, one or more (e.g., each) sensor board 102 may comprise several components that work together to provide localized measurement capabilities, including at least electrical current measurement capabilities, in aquatic environments.

The sensor board 102 may include at least one electrical current sensor 104. In embodiments, the at least one electrical current sensor 104 may be formed as a polyhedral (e.g., tetrahedral) electrode assembly 106 operatively coupled to the sensor board 102. The electrode assembly 106 may be configured for submersion in water to enable three-dimensional electrical current measurement capabilities. The tetrahedral electrode assembly 106 may position four electrodes at the vertices of a tetrahedron to create multiple measurement planes for comprehensive current flow analysis. The sensor board 102 may sequentially measure electrical current between different combinations of three electrodes to construct comprehensive three-dimensional current flow patterns around the sensor location.

The electrical current sensor 104 may comprise measurement circuitry configured to detect electrical current flow in the water surrounding the sensor board 102. The electrical current sensor 104 may be operatively coupled to the electrode assembly 106 to receive electrical signals from the electrodes positioned within the water environment. The electrical current sensor 104 may include analog-to-digital conversion circuitry configured to convert analog voltage measurements from the electrode assembly 106 into digital values for processing by the sensor microcontroller.

The electrical current sensor 104 may implement galvanic isolation circuitry configured to separate the electrode measurement circuits from the main power supply system of the sensor board 102. The galvanic isolation may prevent ground loop interference that could compromise measurement accuracy when multiple sensor boards 102 are connected to a common controller board. The galvanic isolation may enhance system safety by preventing electrical current from the measurement circuits from affecting the main system electronics of the sensor board 102.

The electrical current sensor 104 may include signal conditioning circuitry configured to filter environmental electrical noise and amplify electrode signals to appropriate levels for measurement processing. The signal conditioning circuitry may apply analog filtering techniques to reduce interference from external electromagnetic sources that could affect measurement accuracy. The electrical current sensor 104 may incorporate multiplexing circuitry configured to sequentially connect different combinations of electrodes from the tetrahedral electrode assembly 106 to the measurement circuits.

The electrical current sensor 104 may be configured to apply known voltage potentials across selected electrode pairs and measure the resulting current flow to determine water resistance between electrode combinations. The electrical current sensor 104 may calculate actual current flow in the water using Ohm's law relationships with the measured voltages and calculated resistances. The electrical current sensor 104 may implement differential measurement techniques configured to distinguish actual current leakage from galvanic effects that occur naturally between dissimilar metals in aquatic environments.

The electrode assembly 106 may comprise four electrodes positioned at the vertices of a tetrahedral geometric configuration to enable three-dimensional electrical current measurement capabilities. The tetrahedral electrode assembly 106 may create multiple measurement planes for comprehensive current flow analysis around the sensor location. The electrode assembly 106 may be constructed from noble metal materials such as titanium to minimize galvanic effects that could interfere with accurate current measurements in water environments.

The electrode assembly 106 may be configured for submersion in water with waterproof connections and cable management systems to ensure reliable electrical contact while preventing water ingress into sensitive electronic components. The electrodes of the assembly 106 may be spaced at calibrated distances optimized for measurement sensitivity across a range of current intensities and flow patterns that may occur in aquatic environments. The electrode assembly 106 may include integrated temperature sensors configured to measure local water conditions for automatic calibration adjustments.

The electrode assembly 106 may be mechanically coupled to the sensor board 102 through a ruggedized mounting system configured to withstand harsh marine environments including saltwater exposure, temperature variations, and mechanical stress from water currents. The electrode assembly 106 may incorporate strain relief mechanisms configured to prevent damage to electrical connections during deployment and operation in dynamic water conditions.

In some embodiments, components exposed to water, such as electrode assemblies and housings, may include antifouling coatings or design features intended to resist biofouling from algae or marine growth. Maintenance enhancements may include removable panels or tool-free enclosures to facilitate battery replacement or periodic cleaning of submerged components.

The electrode assembly 106 may enable the sensor board 102 to sequentially measure electrical current between different combinations of three electrodes to construct comprehensive three-dimensional current flow patterns. The tetrahedral configuration may allow the electrode assembly 106 to detect current flow direction and intensity across multiple spatial planes simultaneously. The electrode assembly 106 may provide the sensor board 102 with volumetric measurement capabilities that may detect electrical hazards occurring in complex three-dimensional water environments that traditional two-dimensional measurement approaches may fail to identify.

The sensor board 102 may include a sensor microcontroller 108 configured to perform local measurement processing and generate wake-up signals to the controller board when threshold breach conditions are detected. The sensor microcontroller 108 may execute local signal processing algorithms including minimum and maximum value calculations, threshold detection, and rate of change analysis to predict hazardous conditions before critical thresholds are exceeded.

The sensor microcontroller 108 may be configured to execute local signal processing algorithms to enhance measurement accuracy and system responsiveness. The sensor microcontroller 108 may perform minimum and maximum value calculations on the electrical current measurements obtained from the tetrahedral electrode assembly 106. The sensor microcontroller 108 may calculate statistical parameters including mean values, standard deviations, and variance measurements to characterize the electrical environment around the sensor location.

The sensor microcontroller 108 may implement threshold detection algorithms configured to identify when measured electrical current values exceed predetermined safety limits. The sensor microcontroller 108 may compare real-time measurements against multiple threshold levels including warning thresholds and critical danger thresholds. The sensor microcontroller 108 may generate immediate wake-up signals to the controller board when absolute threshold breaches are detected, enabling rapid system response to hazardous conditions.

The sensor microcontroller 108 may execute rate of change analysis algorithms configured to predict hazardous conditions before critical thresholds are exceeded. The sensor microcontroller 108 may calculate the time derivative of current measurements to identify rapidly increasing current levels that may indicate developing electrical hazards. The sensor microcontroller 108 may apply predictive algorithms to estimate future current levels based on observed trends in the measurement data.

The sensor microcontroller 108 may perform cyclic redundancy check computations to ensure data integrity during communication with the controller board. The sensor microcontroller 108 may implement error detection and correction protocols to maintain reliable data transmission across the digital communication network. The sensor microcontroller 108 may buffer measurement data locally when communication interruptions occur and retransmit stored data when connectivity is restored.

The sensor microcontroller 108 may handle low-level communication protocol functions including message formatting, timing synchronization, and network addressing. The sensor microcontroller 108 may respond to polling requests from the controller board with current measurement data and system status information. The sensor microcontroller 108 may accept configuration commands from the controller board to adjust measurement parameters, threshold values, and sampling rates.

The sensor microcontroller 108 may implement power management functions to optimize energy consumption during extended deployment periods. The sensor microcontroller 108 may adjust measurement frequency based on detected activity levels to conserve power during periods of stable electrical conditions. The sensor microcontroller 108 may enter low-power standby modes while maintaining continuous monitoring capability for threshold breach detection.

Power management operations may further include adaptive adjustment of sensor sampling rates, communication frequency, and alert activation based on real-time assessment of available power reserves. In low-power situations, the system may prioritize essential sensing and notification while deferring non-critical functions to maximize operational life.

In certain embodiments, each sensor board 102 includes a local microcontroller 108, such as an ARM Cortex-M or equivalent, programmed to capture voltage/current data from its electrode array, filter the data to remove electrical noise, and generate hazard detection metrics before transmitting summary values and diagnostic status to the controller board over the network link.

The sensor microcontroller 108 may process temperature sensor data from the embedded temperature sensors within the tetrahedral electrode assembly 106. The sensor microcontroller 108 may apply temperature compensation algorithms to correct electrical current measurements for variations in water temperature that affect conductivity. The sensor microcontroller 108 may calculate correction factors based on temperature measurements to maintain measurement accuracy across seasonal temperature variations.

The sensor microcontroller 108 may coordinate with the galvanic isolation circuitry to ensure proper electrical separation between measurement circuits and power supply systems. The sensor microcontroller 108 may monitor isolation circuit integrity and report fault conditions to the controller board when isolation barriers are compromised. The sensor microcontroller 108 may implement safety protocols to prevent electrical current from measurement circuits from affecting the main system electronics.

The sensor microcontroller 108 may execute differential calculation algorithms to distinguish actual current leakage from environmental electrical noise and galvanic effects. The sensor microcontroller 108 may apply digital filtering techniques to reduce interference from external electromagnetic sources that could affect measurement accuracy. The sensor microcontroller 108 may implement pattern recognition algorithms to identify characteristic signatures of electrical hazards versus natural electrical phenomena in aquatic environments.

The sensor board 102 may further comprise galvanic isolation circuitry 110 configured to separate the tetrahedral electrode assembly from the controller board power supply system. This isolation may prevent ground loop interference and enable accurate current measurements when multiple sensor boards are connected to a common controller board. The galvanic isolation circuitry 110 may enhance system safety by preventing electrical current from the measurement circuits from affecting the main system electronics.

The galvanic isolation circuitry 110 may comprise electrical isolation components configured to provide electrical separation between the tetrahedral electrode assembly 106 and the main power supply system of the sensor board 102. The galvanic isolation circuitry 110 may utilize isolation transformers configured to transfer electrical signals across an isolation barrier while maintaining electrical separation between input and output circuits. The isolation transformers may operate at frequencies optimized for the measurement signals generated by the tetrahedral electrode assembly 106.

The galvanic isolation circuitry 110 may include optocouplers configured to transmit digital control signals across the isolation barrier using optical coupling. The optocouplers may enable the sensor microcontroller 108 to control measurement functions within the isolated measurement circuits without creating electrical connections that could compromise the isolation barrier. The optocouplers may provide bidirectional communication capability to enable both control signal transmission and measurement data feedback across the isolation barrier.

The galvanic isolation circuitry 110 may incorporate isolated power supplies configured to provide power to the measurement circuits on the isolated side of the barrier. The isolated power supplies may derive power from the main sensor board power system while maintaining electrical isolation through transformer coupling or other isolation techniques. The isolated power supplies may provide multiple voltage levels required for analog measurement circuits and digital control functions within the isolated measurement section.

The galvanic isolation circuitry 110 may include isolation amplifiers configured to transfer analog measurement signals from the tetrahedral electrode assembly 106 across the isolation barrier. The isolation amplifiers may maintain signal integrity while providing high common-mode rejection to eliminate ground loop interference that could affect measurement accuracy. The isolation amplifiers may provide gain adjustment capability to optimize signal levels for subsequent analog-to-digital conversion processes.

The galvanic isolation circuitry 110 may implement capacitive isolation techniques configured to transfer high-frequency digital signals across the isolation barrier. The capacitive isolation may utilize specialized integrated circuits that encode digital data into high-frequency carrier signals that can traverse capacitive coupling elements. The capacitive isolation may provide higher data transmission rates compared to optocoupler-based isolation methods.

The galvanic isolation circuitry 110 may include magnetic isolation components configured to transfer power and signals using magnetic coupling techniques. The magnetic isolation may utilize specialized transformers designed for signal isolation applications that provide both power transfer and data communication across the isolation barrier. The magnetic isolation may offer advantages in terms of power efficiency and signal bandwidth compared to other isolation methods.

The galvanic isolation circuitry 110 may incorporate isolation monitoring circuits configured to verify the integrity of the isolation barrier during operation. The isolation monitoring circuits may measure leakage currents across the isolation barrier and generate fault signals when isolation degradation is detected. The isolation monitoring may enable predictive maintenance by identifying isolation barrier degradation before complete failure occurs.

The galvanic isolation circuitry 110 may provide isolation voltage ratings configured to withstand electrical potentials that may occur between the tetrahedral electrode assembly 106 and the main sensor board circuits. The isolation voltage ratings may exceed the maximum expected voltage differences that could occur during normal operation or fault conditions in the monitored water environment. The isolation voltage ratings may comply with safety standards for electrical equipment used in aquatic environments.

The galvanic isolation circuitry 110 may include common-mode filtering components configured to reduce electromagnetic interference that could affect measurement accuracy. The common-mode filtering may utilize inductors and capacitors positioned on both sides of the isolation barrier to attenuate interference signals while preserving measurement signal integrity. The common-mode filtering may be particularly effective at reducing interference from external electromagnetic sources such as marine radio equipment.

The galvanic isolation circuitry 110 may implement differential signal transmission techniques configured to improve noise immunity across the isolation barrier. The differential signal transmission may convert single-ended measurement signals to differential format before transmission across the isolation barrier and reconvert to single-ended format on the receiving side. The differential signal transmission may provide superior noise rejection compared to single-ended signal transmission methods.

The galvanic isolation circuitry 110 may include surge protection components configured to protect the isolation barrier from transient voltage spikes that may occur in marine environments. The surge protection components may utilize gas discharge tubes, varistors, or other transient voltage suppression devices positioned on both sides of the isolation barrier. The surge protection may prevent damage to isolation components from lightning strikes or other high-energy transient events.

The galvanic isolation circuitry 110 may provide multiple isolation channels configured to handle different types of signals simultaneously. The multiple isolation channels may include separate isolation paths for analog measurement signals, digital control signals, and power transfer functions. The multiple isolation channels may enable parallel signal processing while maintaining isolation integrity for each signal type.

The sensor board 102 may include additional environmental sensors 112, such as a temperature sensor, a salinity sensor, a humidity, sensor, and/or the like. One or more of the sensors 112 may be embedded within the tetrahedral electrode assembly 106 to measure local water conditions and enable automatic calibration adjustments. The system may apply correction factors based on environmental measurements to maintain accurate current detection across varying water environments and seasonal conditions. Additionally or alternatively, one or more of the sensors 112 may be disposed internally to measure conditions associated with the platform 100 itself.

The additional environmental sensors 112 may comprise various sensor types configured to measure environmental conditions that may affect electrical current detection accuracy and provide comprehensive monitoring capabilities for the aquatic environment. The environmental sensors 112 may include temperature sensors configured to measure ambient air temperature surrounding the sensor board 102 or water temperature in the immediate vicinity of the tetrahedral electrode assembly 106. The temperature sensors may provide temperature compensation data to enable accurate electrical current measurements across varying thermal conditions that may affect water conductivity and electrode performance.

Alternative embodiments may further include environmental sensors configured to measure pH, dissolved oxygen, water pressure or depth, turbidity, and ambient light intensity. The pH and dissolved oxygen sensors may provide water chemistry and quality data, while water pressure sensors may determine the depth of sensor deployment. Turbidity sensors may assess water clarity, and light intensity sensors may measure ambient conditions to inform automatic brightness adjustment of visual alerts. The data from these sensors may supplement electrical hazard evaluations and support comprehensive environmental monitoring. Data provided by these sensors may be conveyed to the controller board and cloud analytics for comprehensive situational awareness and enhanced calibration across diverse aquatic environments.

The environmental sensors 112 may include humidity sensors configured to measure atmospheric humidity levels in the area surrounding the sensor board 102. The humidity sensors may provide environmental context data that may be transmitted to the controller board for inclusion in comprehensive environmental monitoring reports. The humidity measurements may enable assessment of atmospheric conditions that could affect the performance of electronic components within the sensor board 102 housing.

The humidity sensor may be disposed within the interior of the waterproof enclosure to detect internal moisture levels. Detection of elevated humidity within the housing may trigger maintenance alerts or preemptive system diagnostics to address potential seal degradation or water ingress.

The environmental sensors 112 may include salinity sensors configured to measure the salt content of water in contact with the tetrahedral electrode assembly 106. The salinity sensors may utilize conductivity measurement techniques to determine ionic concentration levels in the water environment. The salinity measurements may enable automatic calibration adjustments to electrical current detection thresholds based on the specific conductivity characteristics of the monitored water environment.

The environmental sensors 112 may include pressure sensors configured to measure water pressure at the depth of the tetrahedral electrode assembly 106 deployment. The pressure sensors may provide depth measurement capabilities that may enable correlation of electrical current measurements with specific water depth levels. The pressure measurements may be particularly useful for sensor boards 102 deployed at varying depths within the same aquatic environment.

The environmental sensors 112 may include pH sensors configured to measure the acidity or alkalinity of water in contact with the tetrahedral electrode assembly 106. The pH sensors may provide water chemistry data that may affect the behavior of electrical currents in the aquatic environment. The pH measurements may enable enhanced analysis of water conditions that could influence electrical current detection accuracy.

The environmental sensors 112 may include dissolved oxygen sensors configured to measure oxygen concentration levels in the water surrounding the tetrahedral electrode assembly 106. The dissolved oxygen sensors may provide water quality data that may be relevant to comprehensive aquatic environment monitoring. The dissolved oxygen measurements may enable assessment of water conditions that could affect the performance of submerged electrical equipment.

The environmental sensors 112 may include turbidity sensors configured to measure water clarity and suspended particle concentration in the vicinity of the tetrahedral electrode assembly 106. The turbidity sensors may utilize optical measurement techniques to assess water transparency levels. The turbidity measurements may provide environmental context data that may be useful for interpreting electrical current measurement results.

The environmental sensors 112 may include flow velocity sensors configured to measure water current speed and direction in the area surrounding the tetrahedral electrode assembly 106. The flow velocity sensors may utilize acoustic or mechanical measurement techniques to determine water movement characteristics. The flow velocity measurements may enable correlation of electrical current detection results with natural water movement patterns.

The environmental sensors 112 may include light intensity sensors configured to measure ambient light levels in the aquatic environment surrounding the sensor board 102. The light intensity sensors may provide data regarding underwater lighting conditions that may affect the visibility of visual alert systems. The light intensity measurements may enable automatic adjustment of visual alert brightness levels based on ambient lighting conditions.

The environmental sensors 112 may include vibration sensors configured to detect mechanical vibrations or seismic activity that may affect the sensor board 102 or tetrahedral electrode assembly 106. The vibration sensors may utilize accelerometer or piezoelectric sensing technologies to detect mechanical disturbances. The vibration measurements may provide diagnostic information regarding the mechanical stability of sensor board 102 installations.

A communication interface 114 may be integrated within the sensor board 102 to provide digital communication (e.g., wired and/or wireless communication) with other portions of the platform 100. For example, the interface 114 may enable communication between the sensor board 102 and a controller board.

The communication interface 114 may comprise hardware and software components configured to enable digital communication between the sensor board 102 and other components of the platform 100. The communication interface 114 may implement digital communication protocols optimized for reliable data transmission over extended distances in harsh marine environments. The interface 114 may utilize differential signaling techniques to improve noise immunity and signal integrity across long cable runs between sensor boards 102 and the controller board.

The communication interface 114 may support multiple network topologies including daisy-chain and star configurations to accommodate various deployment scenarios. The interface 114 may implement automatic network discovery protocols to enable plug-and-play connectivity when sensor boards 102 are added to or removed from the network. The communication interface 114 may include error detection and correction capabilities using cyclic redundancy check algorithms to ensure data integrity during transmission.

The communication interface 114 may handle bidirectional communication to enable both data transmission from the sensor board 102 to the controller board and command reception from the controller board to the sensor board 102. The interface 114 may implement message queuing capabilities to buffer data during temporary communication interruptions and retransmit stored messages when connectivity is restored. The communication interface 114 may support variable data rates to optimize bandwidth utilization based on measurement frequency and system requirements.

The communication interface 114 may include network addressing capabilities to enable unique identification of each sensor board 102 within a multi-sensor network. The interface 114 may implement collision detection and avoidance protocols to prevent data corruption when multiple sensor boards 102 attempt simultaneous transmission. The communication interface 114 may support priority-based message handling to ensure critical alarm signals receive immediate transmission precedence over routine measurement data.

The communication interface 114 may incorporate power line communication capabilities to enable simultaneous power delivery and data transmission over the same cable infrastructure. The interface 114 may implement galvanic isolation between communication circuits and power delivery circuits to prevent ground loop interference and enhance measurement accuracy. The communication interface 114 may include surge protection components to protect against transient voltage spikes that may occur in marine environments.

The communication interface 114 may support wake-up signaling protocols to enable power-efficient operation while maintaining rapid response to hazardous conditions. The interface 114 may implement low-power standby modes that maintain communication capability while reducing overall system power consumption. The communication interface 114 may include automatic reconnection capabilities to restore communication links after power interruptions or cable disconnections.

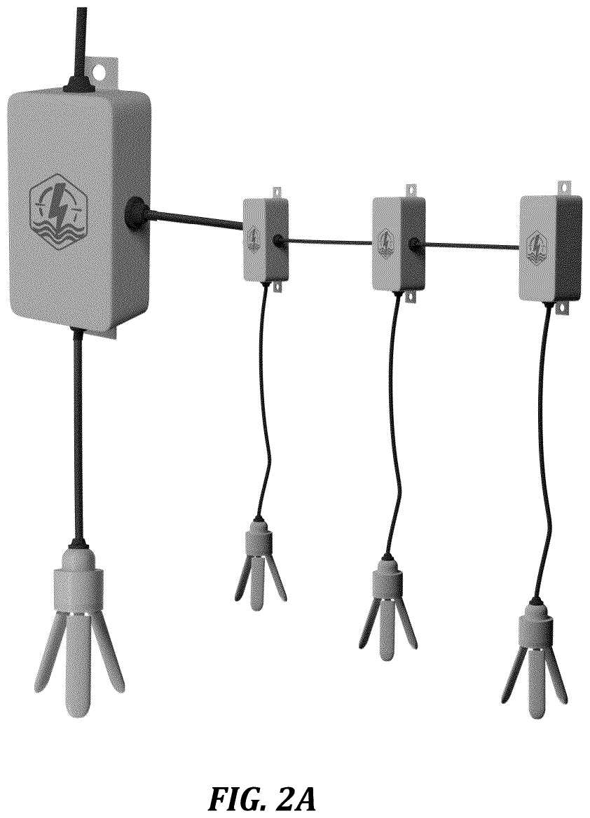

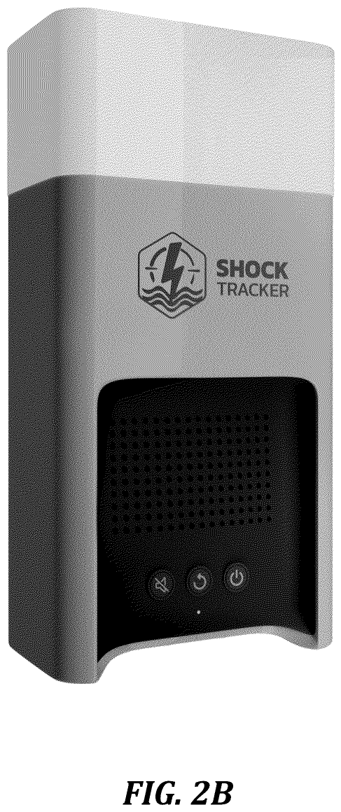

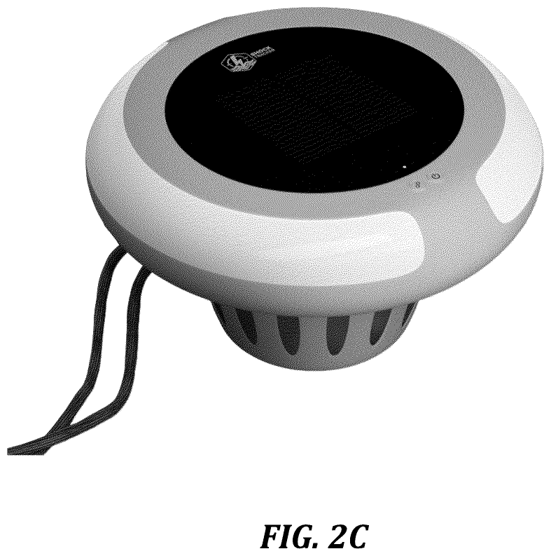

FIG. 2A shows one example embodiment of a plurality of interconnected sensor devices 102.

### B. A Controller Board

The platform 100 may include at least one controller sub-assembly or controller board 102. As best shown in FIG. 1C, the controller board 120 may serve as the central coordination unit for the electrical safety monitoring system. The controller board 120 may include a microcontroller 122 configured to process measurement data received from multiple sensor boards and coordinate system-wide safety responses. The microcontroller 122 may execute digital signal processing algorithms to analyze current flow patterns and determine hazardous conditions based on processed sensor data.

The microcontroller 122 may be configured to execute central processing functions for the electrical safety monitoring system. The microcontroller 122 may receive measurement data from multiple sensor boards through the digital communication network and process this data to determine system-wide electrical hazard conditions. The microcontroller 122 may implement digital signal processing algorithms to analyze current flow patterns detected by the distributed sensor network.

The microcontroller 122 may coordinate safety responses across the entire monitoring system when hazardous conditions are detected. The microcontroller 122 may generate control signals to activate visual alert components and audible alert systems based on processed measurement data from connected sensor boards. The microcontroller 122 may determine alert severity levels and select appropriate response patterns for the light-emitting diodes and siren based on the magnitude and characteristics of detected electrical hazards.

The microcontroller 122 may manage communication protocols with the wireless communication module to transmit measurement data and system status information to cloud-based monitoring systems. The microcontroller 122 may format data packets containing electrical current measurements, environmental sensor readings, and system operational parameters for transmission to remote servers. The microcontroller 122 may handle authentication and encryption protocols to ensure secure data transmission across wireless networks.

The microcontroller 122 may execute power management functions to optimize energy consumption across the distributed monitoring system. The microcontroller 122 may monitor battery charge levels and automatically switch between available power sources including grid power, solar power, and internal battery backup. The microcontroller 122 may implement power-saving modes during periods of stable electrical conditions while maintaining continuous monitoring capability through wake-up signaling from sensor board microcontrollers.

The microcontroller 122 may process wake-up signals received from sensor board microcontrollers when threshold breach conditions are detected at remote sensor locations. The microcontroller 122 may immediately activate from power-saving modes upon receiving wake-up signals to ensure rapid system response to electrical hazards. The microcontroller 122 may coordinate with sensor board microcontrollers to verify hazard conditions and initiate appropriate safety responses.

The microcontroller 122 may manage the user interface elements including the display and navigation buttons integrated within the controller board. The microcontroller 122 may generate display content showing status information for each connected sensor board, power source conditions, and grid voltage parameters. The microcontroller 122 may process user input from navigation buttons to enable local configuration adjustments and system status review.

The microcontroller 122 may implement grid power monitoring functions to continuously assess electrical supply conditions. The microcontroller 122 may detect fault conditions including ground voltage presence, voltage imbalance, undervoltage, and overvoltage conditions that may contribute to electrical hazards in water. The microcontroller 122 may automatically trigger ground fault circuit interrupter mechanisms when dangerous current levels are detected in monitored water areas.

The microcontroller 122 may coordinate ground loop potential measurements between multiple sensor boards when multiple sensors are deployed within the monitoring system. The microcontroller 122 may analyze ground loop conditions to determine when enhanced measurement modes may be safely enabled using temporary ground connections between sensor locations. The microcontroller 122 may verify safe ground loop conditions before authorizing enhanced measurement capabilities.

The microcontroller 122 may process environmental sensor data (e.g., received from the one or more sensor boards 102) including temperature measurements from sensor boards to enable automatic calibration adjustments. The microcontroller 122 may apply correction factors based on environmental variations such as (but not limited to) water temperature variations to maintain accurate current detection across changing environmental conditions. The microcontroller 122 may adjust detection thresholds dynamically based on environmental factors that affect water conductivity.

The microcontroller 122 may implement network management functions to maintain communication with multiple sensor boards connected through the digital signal network. The microcontroller 122 may monitor connectivity status of each sensor board and detect communication interruptions or sensor board failures. The microcontroller 122 may generate diagnostic information regarding sensor board operational status and communication network integrity.

The microcontroller 122 may execute firmware update procedures when commanded through the wireless communication module. The microcontroller 122 may receive firmware updates from cloud-based systems and coordinate update deployment across connected sensor boards. The microcontroller 122 may verify firmware integrity and manage update installation processes to ensure continued system operation during maintenance activities.

In some embodiments, the disclosure contemplates a non-transitory computer-readable medium storing instructions executable to perform any methods described herein, including system initialization, measurement, fault detection, reporting, and alert escalation. The platform may support downloadable updates or firmware upgrades for both server and device-side components, enabling feature expansion, security patches, and regulatory compliance modifications after initial deployment.

The microcontroller 122 may log measurement data and system events in local memory for diagnostic purposes and historical analysis. The microcontroller 122 may maintain event logs including electrical hazard detections, system alerts, power source changes, and communication status information. The microcontroller 122 may provide diagnostic data to support system maintenance and performance optimization activities.

The controller board 120 may include a display 124 configured to present status information for each connected sensor board. The display 124 may show operational parameters including power source status, grid voltage conditions, and individual sensor board connectivity. The display 124 may provide limited vital information while primary system interface may be accessed through mobile applications and cloud-based portals.

The display 124 may comprise a display (e.g., liquid crystal display, OLED display, e-paper display, and/or any other suitable display technology) configured to present operational status information for the distributed monitoring system. The display 124 may show connectivity status for each sensor board connected to the controller board through the digital communication network. The display 124 may present power source information including grid voltage levels, battery charge status, and solar panel output when solar charging capability is available.

The display 124 may be configured to show individual sensor board operational parameters including measurement status, communication link quality, and power consumption levels for each connected sensor board. The display 124 may present grid power monitoring information including voltage measurements, frequency readings, and fault condition indicators when grid power is available to the controller board. The display 124 may show environmental data received from sensor boards including water temperature measurements and calibration status information.

The display 124 may present system alert status information including current hazard detection levels and alarm activation status. The display 124 may show historical event information including recent electrical hazard detections and system maintenance activities. The display 124 may be configured to present network topology information showing the configuration and connectivity status of multiple sensor boards connected to the controller board.

The display 124 may include backlighting capability to enable visibility in low-light conditions that may occur in marine environments during nighttime operations. The display 124 may be configured with adjustable brightness levels to optimize visibility across varying ambient lighting conditions. The display 124 may utilize a monochrome or color display technology depending on the information complexity requirements for the monitoring system.

The display 124 may be integrated within a protective housing that provides resistance to moisture and environmental contamination that may occur in marine deployment environments. The display 124 may include anti-glare coating or surface treatment to maintain visibility when exposed to direct sunlight or bright lighting conditions. The display 124 may be positioned within the controller board housing to enable viewing through a transparent window or protective cover.

The display 124 may present information in multiple display modes including summary status screens and detailed diagnostic information screens. The display 124 may cycle through different information screens automatically or may be controlled through user input via the navigation buttons integrated within the controller board. The display 124 may show system configuration information including sensor board network addresses and communication protocol settings.

The display 124 may present real-time measurement data from connected sensor boards including current detection levels and environmental sensor readings. The display 124 may show system operational time information including uptime statistics and maintenance schedule indicators. The display 124 may be configured to present error condition information including communication failures and sensor board diagnostic alerts.

The display 124 may include power management features to reduce energy consumption during extended battery-powered operation. The display 124 may enter low-power standby modes when user interaction is not detected while maintaining the ability to immediately activate when system alerts occur. The display 124 may adjust refresh rates based on the type of information being presented to optimize power consumption while maintaining adequate information update frequency.

The controller board 120 may include one or more navigation buttons 126 configured to enable local interface control and display menu navigation. At least one (e.g., each) of the one or more navigation buttons 126 may allow users to scroll through system status displays, access configuration menus at the controller board location, and/or otherwise provide user input.

The navigation button 126 may be configured to enable user interaction with the controller board display system and menu navigation functions. The navigation button 126 may comprise a physical input mechanism configured to receive user input for controlling display content and accessing system configuration options. The navigation button 126 may be positioned on the controller board housing to provide convenient access for users operating the system at dock locations.

The one or more navigation buttons 126 may be configured to enable scrolling through multiple display screens showing different categories of system information. The one or more navigation buttons 126 may allow users to cycle through status displays for individual sensor boards connected to the controller board. The one or more navigation buttons 126 may provide access to grid power monitoring information including voltage levels, frequency measurements, and fault condition indicators when grid power is available to the controller board.

The one or more navigation buttons 126 may enable navigation through environmental data displays showing water temperature measurements received from sensor boards and calibration status information for the distributed sensor network. The one or more navigation buttons 126 may provide access to system alert status information including current hazard detection levels and alarm activation status. The one or more navigation buttons 126 may allow users to view historical event information including recent electrical hazard detections and system maintenance activities.

The one or more navigation buttons 126 may be configured to provide access to network topology information showing the configuration and connectivity status of multiple sensor boards connected to the controller board. The one or more navigation buttons 126 may enable users to access system configuration menus for adjusting measurement parameters, threshold values, and communication settings. The one or more navigation buttons 126 may allow users to initiate diagnostic functions and system status checks for connected sensor boards.

The one or more navigation buttons 126 may be configured to support multiple input methods including single press actions for basic navigation and extended press actions for accessing advanced configuration options. The one or more navigation buttons 126 may be integrated with or otherwise operatively connected to the microcontroller 122 of the controller board 120 through digital input circuits that provide reliable signal detection.

The one or more navigation buttons 126 may enable users to acknowledge alarm conditions, reset alert states after hazardous conditions have been resolved and/or allow users to manually initiate communication tests with connected sensor boards to verify network connectivity and operational status.

The controller board 120 may include one or more visual alert components 128. At least one of the one or more visual alert components 128 may be a light-emitting diode or other light source configured to provide immediate hazard notifications. The visual alert components 128 may generate programmable color patterns and brightness levels to indicate different types of hazards detected in the monitored water area.

The visual alert components 128 may comprise light-emitting diodes and/or other high-intensity light bulbs (e.g., halogen bulbs, incandescent bulbs, etc.) configured to provide immediate hazard notifications through programmable color patterns and brightness levels. The light-emitting diodes may be configured to generate high-intensity visual alerts with brightness levels that may enable visibility across various lighting conditions encountered in aquatic environments. The visual alert components 128 may utilize RGBW light-emitting diodes that may provide red, green, blue, and white color capabilities for generating distinct alert colors and/or patterns based on detected hazard conditions.

The light-emitting diodes of the visual alert components 128 may be positioned within the controller board housing to provide optimal visibility from multiple viewing angles around the installation location. The visual alert components 128 may be configured with brightness levels that may reach approximately 300 lumens to ensure visibility during daylight conditions and bright ambient lighting that may occur in outdoor marine environments. The light-emitting diodes may be configured to operate across extended temperature ranges that may be encountered in various deployment environments.

The visual alert components 128 may implement programmable color patterns that may correspond to different types of electrical hazards detected by the sensor boards connected to the controller board. The light-emitting diodes may generate solid color displays for steady-state hazard conditions and flashing patterns for critical alert conditions that may require immediate attention from personnel in the vicinity. The visual alert components 128 may be configured to display different colors simultaneously to convey multiple types of status information including system operational status and hazard severity levels.

The controller board microcontroller 122 may control the visual alert components 128 through digital signal interfaces that may enable precise control of color selection, brightness levels, and timing patterns for the light-emitting diodes. The visual alert components 128 may be configured to respond immediately to wake-up signals received from sensor board microcontrollers when threshold breach conditions are detected at remote sensor locations. The light-emitting diodes may be configured to maintain consistent color accuracy across varying ambient temperature conditions that may affect the performance of semiconductor light sources.

The visual alert components 128 may include protective housings or covers that may provide resistance to moisture ingress and environmental contamination while maintaining optical clarity for light transmission. The light-emitting diodes may be configured with heat dissipation mechanisms that may prevent thermal damage during extended operation periods or high ambient temperature conditions. The visual alert components 128 may implement power management features that may optimize energy consumption while maintaining adequate brightness levels for hazard notification purposes.

In some embodiments, the system may be configured to receive commands from a remote user interface via a cloud-based service, enabling remote activation of the audible and visual alert systems regardless of whether a local hazard is detected. This remote alarm capability may facilitate evacuation, safety drills, or other alerts independently of local sensor readings.

The visual alert components 128 may be configured to operate in coordination with the audible alert system 130 to provide synchronized multi-modal warning signals when dangerous electrical current conditions are detected in the monitored water area. The light-emitting diodes may be programmed to display specific color sequences that may indicate the location of the sensor board that detected the hazardous condition when multiple sensor boards are connected to the controller board. The visual alert components 128 may provide status indication capabilities that may show the operational status of each connected sensor board through distinct color coding systems.

The controller board 120 may include an audible alert system comprising a siren 130 configured to provide an audible alert. The siren 130 may generate high-intensity sound alerts when dangerous current conditions are detected. The siren 130 may produce audio signals with sufficient intensity to alert personnel in the vicinity of the monitored aquatic area.

The siren 130 may comprise an electro-acoustic transducer configured to generate high-intensity audible alerts when dangerous electrical current conditions are detected in the monitored water area. The siren 130 may be configured to produce sound output with sufficient acoustic power to alert personnel across the aquatic environment and surrounding areas. The siren 130 may generate audio signals with intensity levels that may enable effective warning notification even in environments with significant ambient noise from marine equipment, water movement, or other environmental sound sources.

The siren 130 may be configured to produce sound output at intensity levels that may reach approximately 100 decibels or more measured at a standard distance from the device. This sound intensity level may ensure that audible alerts are clearly audible to personnel operating in the vicinity of the monitored aquatic area during both normal and emergency conditions. The siren 130 may be designed to maintain consistent sound output levels across varying environmental conditions including temperature variations and humidity levels that may be encountered in marine deployment environments.

The siren 130 may incorporate weatherproof construction configured to withstand harsh marine environments including saltwater exposure, temperature extremes, and mechanical stress from environmental factors. The siren 130 may include protective housing or enclosure materials that may provide resistance to corrosion and moisture ingress while maintaining acoustic performance characteristics. The protective housing may be constructed from materials that may resist degradation from ultraviolet radiation exposure during outdoor deployment conditions.

The siren 130 may be configured to generate multiple distinct sound patterns that may correspond to different types of electrical hazards detected by the sensor boards connected to the controller board. The siren 130 may produce continuous tone alerts for steady-state hazard conditions and intermittent or pulsed tone patterns for critical alert conditions that may require immediate attention from personnel. The siren 130 may be capable of generating different tone frequencies or sound characteristics to convey information about hazard severity levels or the specific sensor board location that detected the hazardous condition.

The controller board microcontroller 122 may control the siren 130 through digital signal interfaces that may enable precise control of sound pattern selection, volume levels, and timing sequences for the audible alerts. The siren 130 may be configured to respond to signals received from the controller board microcontroller when threshold breach conditions are detected. The siren 130 may be configured to maintain consistent acoustic output characteristics across varying ambient temperature conditions that may affect the performance of electro-acoustic components.

The siren 130 may incorporate directional sound projection capabilities that may focus acoustic output toward areas where personnel are most likely to be present during normal aquatic facility operations. The siren 130 may include acoustic horn or reflector components that may enhance sound projection efficiency and ensure maximum coverage of the monitored area with adequate sound intensity levels. The siren 130 may be positioned within the controller board housing to provide optimal sound transmission while maintaining protection from environmental factors.

The siren 130 may include frequency response characteristics that may be optimized for human hearing sensitivity and sound transmission through air in outdoor environments. The siren 130 may generate sound frequencies that may provide effective penetration through ambient noise while avoiding frequencies that may cause excessive annoyance during extended alert conditions. The siren 130 may be configured to produce sound output that may comply with applicable noise regulations and safety standards for audible warning devices in marine environments.

In some embodiments, the controller board 120 may associate distinct visual and audible alert patterns with the type and severity of detected electrical hazards. For example, steady illumination or a slow pulsing light pattern may indicate a non-critical warning, while rapid flashing and a high-intensity siren may correspond to a critical, immediate danger. The alert system may be programmed to escalate notifications, initially activating local alerts for personnel in the vicinity, then sending electronic notifications to designated facility operators, remote administrators, or emergency responders if hazardous conditions persist or escalate. Escalation parameters, signal timing, and recipient lists may be configurable to match facility policies and regulatory requirements.

The controller board 120 may include a communication module 132 configured to provide wired and/or wireless connectivity for data transmission to cloud-based monitoring systems and mobile applications. Additionally or alternatively, the communication module 132 may facilitate communication between the sensor board 102 and the controller board 120. The communication module 132 may support multiple wireless protocols including cellular connectivity, Wi-Fi connectivity, personal area network (PAN) connectivity (e.g., IEEE 802.15.1 Bluetooth communication, 802.15.4 Zigbee communication, etc.), and/or the like to ensure reliable data transmission across various deployment environments. The communication module 132 may facilitate wired communication standards, such as (but not limited to) ANSI/TIA 568, IEEE 802.3 (e.g., 802.3, 802.3u, 802.3ab, 802.3af, 802.3at, 802.3bt, fiber optic standards, and/or the like), and/or other wired communication standards.

The communication module 132 may comprise hardware and software components configured to enable data transmission between the controller board 120 and remote monitoring systems. The communication module 132 may implement multiple wireless communication protocols to ensure reliable connectivity across diverse deployment environments. The communication module 132 may support cellular communication standards including fourth generation long term evolution and fifth generation wireless protocols to enable data transmission in areas where other wireless networks may not be available.

The communication module 132 may include a Wi-Fi transceiver configured to connect to available wireless local area networks when such networks are accessible at the deployment location. The Wi-Fi transceiver may support multiple wireless standards including (but not limited to) IEEE 802.11b, IEEE 802.11g, IEEE 802.11n, and/or IEEE 802.11ac to ensure compatibility with various wireless network infrastructures. The communication module 132 may automatically detect and connect to available Wi-Fi networks using stored network credentials and authentication parameters.

The primary communication link may use a multi-conductor cable 150 with reinforced, UV-stabilized insulation, protected by a flexible conduit in high-traffic or abrasive environments. All connectors may be rated for underwater use and equipped with locking features. Where physical cable runs are impractical, a short-range wireless transceiver operating in the 2.4 GHz or sub-GHz ISM band may be included in the controller board, hub, and/or sensor boards, allowing redundant or hybrid network operation even if a cable is damaged.

The connection between the controller board 120, extenders 152, and sensor boards 102 may use ruggedized underwater cables that carry both low-voltage DC power and digital data. Alternatively, short-range wireless protocols such as RF or optical signaling may be used for floating sensor boards near the device housing. Cable connectors may be sealed with O-rings and potted to industry standards for subaqueous use, allowing reliable long-term deployment.

In further embodiments, the communication module may support satellite data transmission to provide reliable connectivity in remote or offshore environments where cellular and Wi-Fi networks are unavailable. The satellite interface may enable periodic reporting and remote diagnostics for isolated deployments.

The communication module 132 may implement automatic network selection algorithms that prioritize communication pathways based on signal strength, data transmission reliability, and power consumption considerations. The communication module 132 may utilize Wi-Fi connectivity as the primary communication method when available and automatically switch to cellular communication when Wi-Fi networks are unavailable or unreliable. The communication module 132 may continuously monitor communication link quality and implement automatic reconnection procedures when communication interruptions occur.

The communication module 132 may include data buffering capabilities configured to store measurement data and system status information during periods when wireless communication links are unavailable. The data buffering may utilize local memory storage within the controller board 120 to maintain measurement records until communication connectivity is restored. The communication module 132 may implement data compression algorithms to optimize bandwidth utilization and reduce data transmission costs when using cellular communication networks.

The communication module 132 may support bidirectional communication to enable both data transmission from the controller board 120 to remote servers and command reception from remote monitoring systems. The communication module 132 may receive configuration updates, firmware upgrade commands, and operational parameter adjustments from cloud-based management systems. The communication module 132 may implement authentication and encryption protocols to ensure secure data transmission and prevent unauthorized access to system functions.

The communication module 132 may transmit multiple types of data including electrical current measurements from connected sensor boards, environmental sensor readings, system operational status, power source conditions, and alert notifications. The communication module 132 may format data packets according to standardized communication protocols to ensure compatibility with cloud-based monitoring platforms. The communication module 132 may include timestamp synchronization capabilities to ensure accurate temporal correlation of measurement data across multiple deployed systems.

The communication module 132 may implement power management features to optimize energy consumption during wireless communication operations. The communication module 132 may adjust transmission power levels based on signal strength requirements and may enter low-power standby modes during periods of communication inactivity. The communication module 132 may coordinate with the controller board power management system to prioritize communication functions based on available battery capacity and charging status.

The communication module 132 may support multiple data transmission modes including real-time streaming for critical alert conditions and periodic batch transmission for routine measurement data. The communication module 132 may implement priority-based message handling to ensure immediate transmission of hazard alerts while queuing routine status information for transmission during optimal communication conditions. The communication module 132 may include error detection and correction capabilities to ensure data integrity during wireless transmission across potentially unreliable communication links.

The communication module 132 may incorporate antenna systems optimized for marine deployment environments where the controller board 120 may be exposed to saltwater conditions and electromagnetic interference from marine equipment. The communication module 132 may include multiple antenna configurations to support different wireless communication protocols and may implement antenna diversity techniques to improve signal reception reliability. The communication module 132 may include weatherproof antenna connections and cable management systems to ensure reliable operation in harsh marine environments.

The communication module 132 may implement communication protocol stacks that handle network layer functions including internet protocol addressing, transport layer reliability, and application layer data formatting. The communication module 132 may support multiple communication protocols simultaneously to enable connectivity with different types of remote monitoring systems and cloud service providers. The communication module 132 may include network diagnostic capabilities to monitor communication performance and generate diagnostic information for system maintenance purposes.

The controller board 120 may include ground fault circuit interrupter interface module 134 configured to automatically disconnect grid power when dangerous current levels are detected in water, in a manner similar to the GFCI functionality integrated into some electrical outlets. Alternatively, if the control device 120 is connected to an outlet that includes GFCI circuitry, the module 134 may cause the GFCI circuit integrated into the electrical outlet to trigger, disconnecting the grid power. The ground fault circuit interrupter module 134 may monitor ground loop potentials between multiple sensor boards and the controller board grid connection to enable enhanced measurement modes when safe ground loop conditions are verified.

FIG. 2B shows one example embodiment of a control device 120.

### C. A Power Management System

The power management system 140 may comprise multiple integrated components configured to provide reliable power delivery across various operational scenarios and environmental conditions. The power management system 140 may include a primary power source selection module that may automatically prioritize between available power sources based on system requirements and power quality assessments. The power source selection module may continuously monitor grid power availability, solar panel output levels, and internal battery charge status to determine the optimal power source configuration for sustained system operation.

The power management system 140 may incorporate a grid power monitoring subsystem configured to assess electrical grid conditions when grid power connectivity is available. The grid power monitoring subsystem may measure voltage levels, frequency stability, and phase balance characteristics to detect fault conditions that may compromise system operation or indicate potential electrical hazards. The monitoring subsystem may identify undervoltage conditions, overvoltage conditions, voltage imbalance between phases, and ground voltage presence that may indicate electrical system faults in the monitored environment.

A battery management subsystem within the power management system 140 may regulate charging cycles and discharge characteristics of the internal rechargeable battery. The battery management subsystem may implement charge optimization algorithms to maximize battery life while ensuring adequate power reserves for extended autonomous operation. The subsystem may monitor battery temperature, charge current, and discharge current to prevent overcharging conditions and thermal damage that could compromise battery performance or safety.

The power management system 140 may include a solar power interface module configured to optimize energy harvesting from connected solar panel arrays. The solar power interface module may implement maximum power point tracking algorithms to extract optimal power output from solar panels under varying illumination conditions. The interface module may regulate charging current delivered to the internal battery and may provide power conditioning to ensure stable power delivery to system components during periods of variable solar irradiance.

A power distribution subsystem within the power management system 140 may manage power delivery to sensor boards and other system components. The power distribution subsystem may provide galvanically isolated power outputs to prevent ground loop interference between sensor measurement circuits and the main system power supply. The subsystem may implement short circuit protection, overcurrent protection, and power monitoring capabilities to ensure reliable operation of connected sensor boards and prevent damage from electrical faults.

The power management system 140 may incorporate a power saving control module configured to reduce system power consumption during periods of low activity or reduced battery capacity. The power saving control module may implement dynamic power management strategies including reduced measurement frequency, communication interval adjustment, and selective component shutdown to extend operational life during battery-powered operation. The module may coordinate with sensor board microcontrollers to implement wake-up signaling capabilities that enable rapid system activation when hazardous conditions are detected.

A ground fault circuit interrupter interface within the power management system 140 may provide automatic disconnection capabilities when dangerous current levels are detected in the monitored water environment. The interface may monitor ground loop potentials between multiple sensor board locations and the controller board grid connection to identify electrical fault conditions. When hazardous current conditions are confirmed through sensor measurements, the interface may automatically trigger ground fault circuit interrupter mechanisms to disconnect grid power sources that may be contributing to the electrical hazard.

The power management system 140 may include a power quality analysis module configured to assess electrical characteristics of available power sources and system power consumption patterns. The power quality analysis module may generate diagnostic data regarding power source performance, battery health, and system power efficiency that may be transmitted to cloud-based monitoring systems for remote analysis and maintenance planning. The module may identify trends in power consumption and battery performance that may indicate the need for system maintenance or component replacement.

### D. A Cable System

The cable system 150 may comprise communication and power delivery infrastructure configured to connect the controller board 120 and one or more sensor boards 102. In some embodiments, the cable system 150 may include a power and data bus configured to connect to boards disposed within a single housing. Additionally or alternatively, the cable system 150 may include a ruggedized cable for connecting the controller board 120 and one or more sensor boards 102 through a unified network architecture. The cable system 150 may utilize cables (e.g., CAT8 cables or other shielded twisted-pair cables) that may provide both power distribution and digital communication capabilities over extended distances between system components. The cables may enable reliable data transmission and power delivery while maintaining signal integrity across harsh marine environments where the system may be deployed.

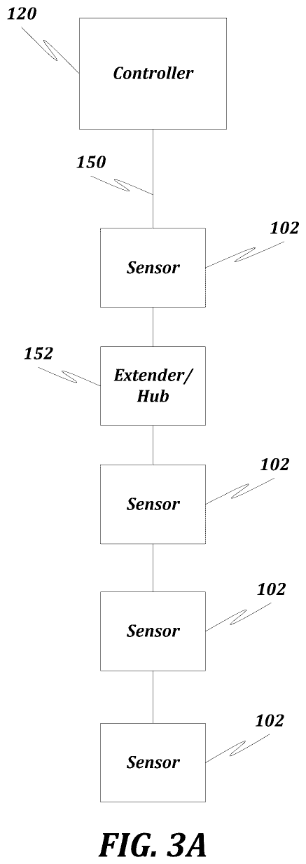

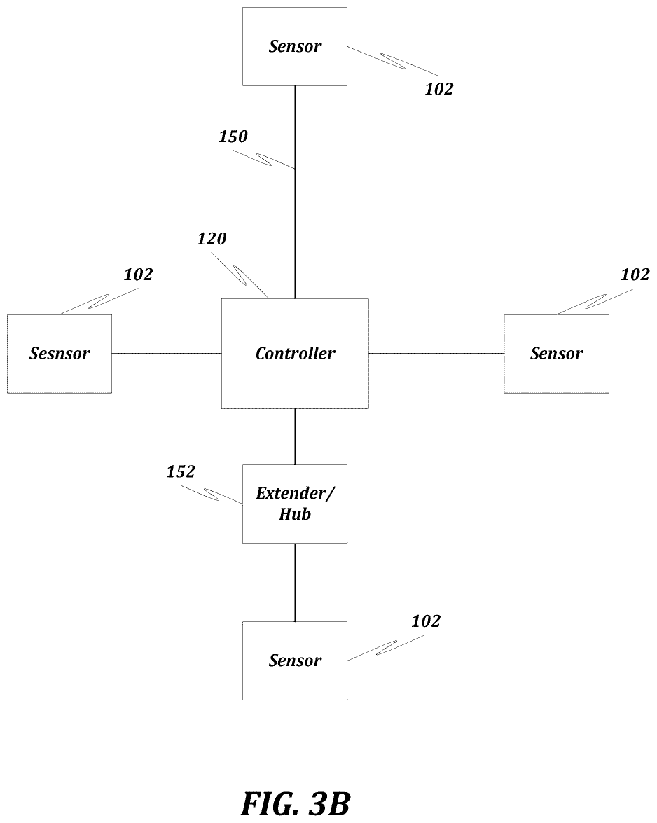

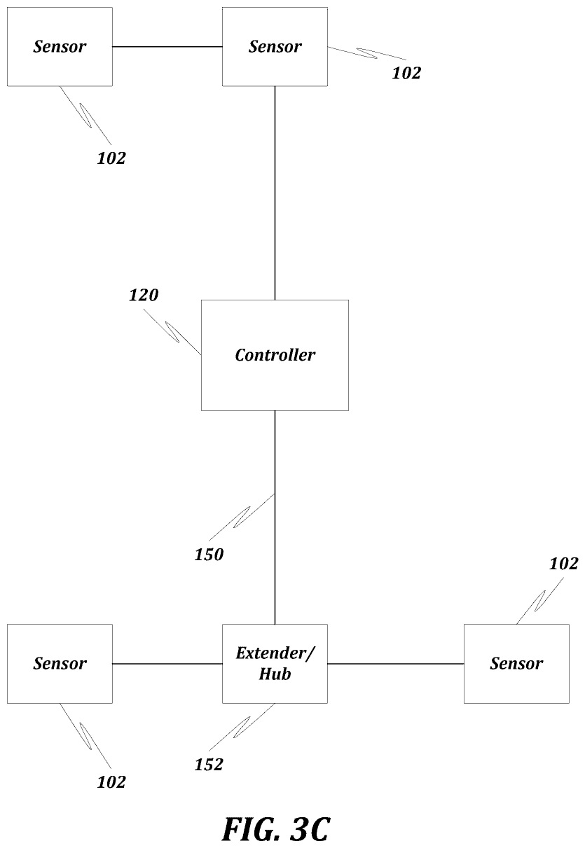

The cable system 150 may implement multiple network topology configurations to accommodate various deployment scenarios and facility layouts. The system may support daisy-chain topology configurations, as shown in FIG. 3A, where sensor boards 102 may be connected sequentially along a single cable run from the controller board 120. The daisy-chain configuration may enable simplified cable management and reduced cable requirements for linear deployment patterns such as dock installations where sensor boards 102 may be positioned at regular intervals along waterfront structures.

In some embodiments, one or more extender devices or hubs 152 may be optionally disposed between the controller board 120 and the sensor boards 102, or between multiple sensor boards, to facilitate modular network expansion or span greater distances within an aquatic facility. The extender devices 152 may comprise signal repeaters, hubs, or similar hardware configured to relay both power and data between the controller board and the connected sensor boards. This configuration may enable flexible installation in daisy-chain, star, or hybrid network topologies, and may allow sensor boards to be deployed at distances or locations that would otherwise exceed direct cabling limits. In certain deployments, extenders 152 may also serve as branching points for sub-networks of sensor boards 102, or may be used to bridge physical obstacles and support robust and scalable monitoring networks. For installations requiring separation over long distances, a hub or extender device 152 may be an inline waterproof enclosure 160 containing passive wiring or active signal repeater electronics. For example, a dock installation may use a single main cable extending from the controller housing to an underwater hub, which then branches to multiple fixed and floating sensor boards arranged in a star network, or connects additional extenders in series to support a daisy-chained line of sensors along a marina.

Hubs or extenders 152 may be manufactured as sealed waterproof boxes with internal bus bars, connectors, or printed circuit boards designed for multi-channel signal routing. Each hub can connect two or more sensor boards in a star or daisy-chain, using color-coded waterproof cables with keyed connectors to prevent miswiring. The hub enclosure may be rated to IP68 or higher and may include strain-relief mounting for cable management in submerged or dockside installations.

Additionally or alternatively, the cable system 150 may support star network topology configurations, as shown in FIG. 3B, where individual cable runs may connect each sensor board 102 directly to the controller board 120. The star topology configuration may provide enhanced reliability by eliminating single points of failure that could affect multiple sensor boards 102 simultaneously. The star configuration may enable independent operation of each sensor board 102 even when other sensor boards 102 may experience communication or power interruptions. In some embodiments, the star and daisy chain topologies may be combined to create a hybrid network topology, as shown in FIG. 3C.

The controller board 120 may implement a digital communication protocol, such as (but not limited to) RS-485, CAN bus, or Modbus, permitting it to assign each sensor board a unique network address. During operation, the controller 120 may periodically poll each sensor board 102, obtain individual measurement data and health/status indicators, and may retrieve location information which may be configured at installation (e.g., dock ID, slip number, GPS coordinates stored in sensor memory). This approach supports dynamic adaptation and coordinated hazard monitoring across all connected sensor boards.

In one embodiment, the controller board 120 is mounted securely inside a waterproof device housing 160 constructed from corrosion-resistant materials such as polycarbonate or marine-grade stainless steel. The housing may be fixed in place to a structure such as a dock piling, electrical cabinet, or a buoy anchor platform, and is designed to isolate the controller board 120 from water, particulate, and UV exposure. Each sensor board 102 may be housed in a modular enclosure 160 rated for submersion or surface flotation. A fixed sensor board 102 may be attached using stainless fasteners, brackets, or adhesive anchors to swim ladders, pilings, or pool walls, while a floating sensor board may incorporate integral floats, outriggers, or tether lines allowing it to remain at or near the water's surface, optionally anchored laterally for positional stability.

In various embodiments, the controller board 120 may be disposed within a fixed device housing 160 located at a centralized installation point, such as a dock or shore location. One or more sensor boards 102 may be positioned in the aquatic environment, either mounted in fixed orientations to submerged infrastructure or configured as floating devices (e.g., anchored or freely drifting), depending at least in part on monitoring requirements. Each sensor board 102 may connect to the controller board 120 directly or indirectly through one or more extenders, hub devices, or repeater modules 152, the extenders being disposed either between the controller board and the sensor boards, or between multiple sensor boards, in order to relay both power and data over extended distances and support modular, scalable network topologies. The controller board 120 may communicate with each sensor board 102 via these network components, and each sensor board may comprise a local microcontroller configured for preliminary signal processing and status reporting. This arrangement enables coordinated monitoring of diverse aquatic environments, with selectable network architecture supporting daisy-chain, star, or hybrid layouts of fixed and/or floating sensor nodes adapted to the monitored facility.

The cables within the cable system 150 may provide galvanically isolated power delivery to prevent ground loop interference between sensor measurement circuits and the controller board power supply system. The galvanic isolation may ensure accurate current measurements when multiple sensor boards 102 may share common power distribution from the controller board 120. The isolation may enhance system safety by preventing electrical current from measurement circuits from affecting the main system electronics within the controller board 120.

The cable system 150 may incorporate short circuit protection mechanisms to prevent damage to system components when electrical faults may occur within the cable infrastructure or connected sensor boards 102. The short circuit protection may automatically disconnect power to affected cable segments while maintaining power delivery to unaffected portions of the sensor network. The protection mechanisms may enable continued system operation even when individual sensor boards 102 or cable segments may experience electrical faults.

The cables may be constructed with ruggedized materials and protective sheathing designed to withstand harsh marine environments, including saltwater exposure, temperature variations, mechanical stress from environmental factors, and/or the like. The cables may incorporate waterproof connectors and strain relief mechanisms to prevent damage to electrical connections during deployment and operation in dynamic marine conditions. The ruggedized construction may ensure reliable long-term operation in challenging deployment environments.

The cable system 150 may include one or more amplifiers, relays or repeaters to support extended cable runs that may enable sensor board deployment at significant distances from the location of the controller board 120. The extended range capability may provide flexibility in system deployment configurations and may enable monitoring coverage of large aquatic facilities such as marina complexes and industrial water treatment installations. The signal conditioning and amplification within the cable system 150 may maintain communication reliability across extended distances.

The cable system 150 may implement digital signal transmission protocols that may provide noise immunity compared to analog signal transmission methods. The digital protocols may enable reliable communication across long cable runs even in electrically noisy marine environments where electromagnetic interference from marine equipment may be present. The digital transmission may include error detection and correction capabilities to ensure data integrity during communication between system components.

The cable system 150 may provide bidirectional communication capabilities to enable both data transmission from sensor boards 102 to the controller board 120 and command transmission from the controller board 120 to sensor boards 102. The bidirectional communication may enable remote configuration of sensor board parameters and firmware updates without requiring physical access to sensor board locations. The communication capabilities may support real-time coordination between system components for enhanced measurement accuracy and system responsiveness.

The cable system 150 may incorporate cable management features including protective conduits, mounting brackets, and/or routing guides to ensure proper cable installation and protection in marine deployment environments. The cable management features may prevent cable damage from mechanical stress, environmental exposure, and marine traffic that may occur around dock installations. The management system may enable organized cable routing that may facilitate system maintenance and expansion activities.

The cable system 150 may support hot-swappable connections that may enable sensor boards 102 to be disconnected and reconnected without affecting the operation of other system components. The hot-swappable capability may enable system maintenance and sensor board replacement activities without requiring complete system shutdown. The capability may enhance system availability and may reduce maintenance downtime for critical monitoring applications.

The cable system 150 may implement network addressing and device identification protocols that may enable automatic discovery and configuration of sensor boards 102 when they may be connected to the network. The automatic discovery may simplify system installation and expansion by eliminating manual configuration requirements for new sensor board additions. The addressing protocols may enable unique identification of each sensor board 102 within the network for coordinated measurement and control functions. ps E. A Housing

The platform 100 may include a housing configured to shield components of the platform from the ambient environment. The housing 160 may be configured to accommodate the controller board 120 and/or the sensor board 102 components depending on the specific deployment configuration selected for the monitoring system. In floating device embodiments, the housing 160 may integrate both controller board 120 and sensor board 102 functionality within a single waterproof enclosure designed for temporary deployment in aquatic environments. The integrated housing 160 may incorporate hydrodynamic design features that may minimize water resistance and provide stable floating characteristics when deployed as a monitoring buoy or temporary sensing device.

The housing 160 for the controller board 120 may comprise a ruggedized industrial enclosure suitable for permanent dock pole mounting applications. The controller board housing 160 may be constructed from corrosion-resistant materials that may withstand prolonged exposure to marine environments including saltwater spray, temperature variations, and ultraviolet radiation from solar exposure. The housing 160 may include mounting brackets and hardware configured to enable secure attachment to dock structures, pier posts, or other fixed infrastructure within the monitored aquatic facility.

The controller board housing 160 may incorporate transparent windows or viewing panels that may enable visibility of the integrated display 124 and visual alert components 128 while maintaining weatherproof protection for internal electronics. The transparent panels may be constructed from impact-resistant polycarbonate or similar materials that may provide optical clarity while resisting damage from environmental factors or accidental impact during dock operations.

Ventilation systems within the controller board housing 160 may include moisture-resistant vents or breathing systems that may prevent internal condensation while maintaining waterproof integrity. The ventilation systems may utilize hydrophobic membrane materials that may allow air exchange while preventing water ingress during rain or spray conditions that may occur in marine deployment environments.

The housing 160 for sensor boards 102 may comprise compact ruggedized enclosures designed for deployment in harsh marine environments where direct water contact and submersion may occur. The sensor board housing 160 may be rated to appropriate ingress protection standards such as IP68 to ensure reliable operation when partially or completely submerged during normal monitoring operations. The sensor board housing 160 may include integrated cable management systems that may provide strain relief and waterproof sealing for communication and power cables connecting to the controller board 120.

The sensor board housing 160 may incorporate mounting provisions that may enable secure attachment to dock structures, pier pilings, or underwater mounting hardware positioned at strategic locations throughout the monitored aquatic area. The mounting systems may include adjustable brackets that may accommodate various installation angles and orientations to optimize electrode assembly positioning for measurement accuracy and coverage requirements.

FIG. 2C shows an example of a floating housing 160 configured to retain both the sensor board 102 and the controller 120. The floating housing option may provide enhanced deployment flexibility for temporary monitoring applications or locations where permanent installation may not be practical or permitted. The floating housing 160 may integrate controller board 120 and sensor board 102 functionality within a single buoyant enclosure that may maintain stable positioning when deployed as an anchored monitoring buoy or free-floating sensing device. The floating housing 160 may incorporate ballast systems or weight distribution features that may ensure proper orientation and stability when deployed in various water conditions including currents, waves, or wind-induced surface disturbances.

The floating housing 160 may include integrated solar panel mounting surfaces that may optimize solar energy collection for autonomous power generation during extended deployment periods. The solar panel integration may be designed to maintain optimal solar exposure angles while preserving the hydrodynamic characteristics and stability of the floating housing 160. The floating housing 160 may incorporate GPS antenna positioning that may ensure reliable satellite signal reception for location tracking and positioning functions.

Tethering points and anchor attachment hardware may be integrated within the floating housing 160 to enable secure positioning and retrieval operations. The tethering systems may include corrosion-resistant hardware and quick-release mechanisms that may facilitate rapid deployment and recovery operations from boats or dock locations. The floating housing 160 may include high-visibility markings or integrated lighting systems that may enhance visibility for marine traffic safety and device location identification during daylight and nighttime conditions.

The floating housing 160 may incorporate impact-resistant construction that may withstand contact with boats, dock structures, or debris that may be encountered in active marine environments. The housing materials may be selected to provide durability while maintaining neutral buoyancy characteristics that may not require excessive ballast or flotation systems that could compromise the compact design requirements for portable deployment applications.

### F. A Power Source

The power source 170 may comprise multiple power options configured to provide reliable electrical energy to the platform 100 across various deployment scenarios and environmental conditions. The power source 170 may include battery power capabilities that may enable autonomous operation during periods when external power sources may be unavailable or unreliable. The battery power option may utilize rechargeable lithium-ion battery technology configured to provide extended operational life while maintaining compact form factor requirements for portable deployment applications.

The power source 170 may incorporate grid power connectivity that may enable continuous operation when alternating current electrical supply may be available at the deployment location. Grid power may be particularly suitable for permanent dock-mounted installations where reliable electrical infrastructure may be accessible through marina electrical systems or shore power connections. The grid power interface may include voltage monitoring capabilities that may continuously assess electrical supply conditions and detect fault conditions that could affect system operation or indicate potential electrical hazards in the monitored environment.

The power source 170 may include renewable energy options that may provide sustainable power generation for extended autonomous operation without requiring external electrical connections. Solar power generation may be implemented through photovoltaic panel arrays that may convert solar irradiance into electrical energy for charging internal battery systems and powering system components. The solar power option may be particularly advantageous for floating device deployments or remote monitoring locations where grid power infrastructure may not be available.

Solar panel integration within the power source 170 may include maximum power point tracking algorithms that may optimize energy harvesting efficiency across varying illumination conditions throughout daily and seasonal cycles. The solar charging system may incorporate battery management circuitry that may regulate charging current and voltage to maximize battery life while ensuring adequate power reserves for continuous monitoring operations. Solar panel positioning may be optimized to maximize solar exposure while maintaining hydrodynamic characteristics for floating deployments or weather resistance for dock-mounted installations.

The power source 170 may implement intelligent power management that may automatically prioritize between available power sources based on system requirements, power quality assessments, and energy availability. The power management system may utilize grid power as the primary source when available while maintaining battery backup for uninterrupted operation during grid power interruptions. Solar power may supplement grid charging or provide primary power generation when grid connectivity may not be available.

Battery backup capabilities within the power source 170 may provide continuous operation during temporary grid power outages or periods of insufficient solar irradiance. The battery system may be sized to support extended autonomous operation while maintaining all safety monitoring functions including current detection, alert generation, and communication capabilities. Battery charge monitoring may provide real-time status information that may be transmitted to remote monitoring systems for maintenance planning and system reliability assessment.

The power source 170 may include power conditioning circuitry that may provide stable voltage and current delivery to system components regardless of the selected power source. Power conditioning may include voltage regulation, filtering, and surge protection to ensure reliable operation of sensitive electronic components including microcontrollers, communication modules, and sensor circuits. The power conditioning system may maintain consistent performance across varying input voltage conditions that may occur with different power source options.

Renewable energy integration within the power source 170 may extend beyond solar power to include wind power generation for deployments in locations with consistent wind resources. Wind power generation may utilize small-scale turbine systems that may be integrated with floating device configurations or mounted as auxiliary power sources for dock-mounted installations. The wind power option may provide supplemental energy generation during periods of reduced solar irradiance or increased power demand.

The power source 170 may incorporate energy storage optimization that may balance power generation, consumption, and storage capacity to maximize operational reliability and minimize maintenance requirements. Energy storage may utilize advanced battery chemistry that may provide high energy density, extended cycle life, and reliable performance across temperature variations encountered in marine deployment environments. The energy storage system may include thermal management features that may maintain optimal battery operating temperatures for maximum performance and longevity.

Power delivery infrastructure within the power source 170 may include multiple output voltages and current capabilities to support different system components with varying power requirements. The power delivery system may provide galvanically isolated outputs to prevent ground loop interference between measurement circuits and main system power supplies. Power monitoring capabilities may track consumption patterns and identify potential efficiency improvements or component degradation that could affect system reliability.

### III. Platform Operation

Embodiments of the present disclosure provide a hardware and software platform operative by a set of methods and computer-readable media comprising instructions configured to operate the aforementioned modules and computing elements in accordance with the methods. The following depicts an example of at least one method of a plurality of methods that may be performed by at least one of the aforementioned modules. Various hardware components may be used at the various stages of operations disclosed with reference to each module.

For example, although methods may be described as being performed by a single computing device, it should be understood that, in some embodiments, different operations may be performed by different networked elements in operative communication with the computing device. For example, at least one computing device 500 may be employed in the performance of some or all of the stages disclosed with regard to the methods. Similarly, an apparatus may be employed in the performance of some or all of the stages of the methods. As such, the apparatus may comprise at least those architectural components found in computing device 500.

Furthermore, although the stages of the following example method are disclosed in a particular order, it should be understood that the order is disclosed for illustrative purposes only. Stages may be combined, separated, reordered, and various intermediary stages may exist. Accordingly, it should be understood that the various stages, in various embodiments, may be performed in arrangements that differ from the ones described below. Moreover, various stages may be added or removed from the method without altering or departing from the fundamental scope of the depicted methods and systems disclosed herein.

### A. Master Method

Consistent with embodiments of the present disclosure, a method may be performed by at least one of the aforementioned modules. The method may be embodied as, for example, but not limited to, computer instructions, which, when executed, perform the method.

The method may provide a comprehensive approach for detecting electrical current in water using a modular water current detection system. The method may begin with initializing communication between a controller board and at least one sensor board via a digital signal network. This initialization phase may establish the communication protocols and network topology required for coordinated operation between the distributed system components.

The method may utilize a submerged tetrahedral electrode assembly of the at least one sensor board in water. In some embodiments (e.g., those attached to a dock or marina), the electrode assembly may be permanently or semi permanently positioned such that the assembly is submerged under water in the area of interest. In other embodiments (e.g., portable embodiments), the electrode assembly may be submerged in the area of interest as a part of deploying the device. The tetrahedral electrode assembly may be positioned at the desired monitoring location within the aquatic environment to enable three-dimensional electrical current measurement capabilities. The submersion may place the four electrodes at the vertices of the tetrahedron in direct contact with the water environment to be monitored.

The method may continue with measuring electrical current between different combinations of three electrodes from the tetrahedral electrode assembly to determine three-dimensional current flow patterns. The sensor board may sequentially activate different electrode combinations to construct comprehensive current flow measurements across multiple spatial planes. Each measurement cycle may utilize three of the four available electrodes to define a measurement plane, with the system cycling through the available combinations to build a complete three-dimensional current flow pattern around the sensor location.

The method may include processing the measurements locally at the sensor board using a sensor microcontroller to detect absolute threshold breaches. The sensor microcontroller may execute local signal processing algorithms including minimum and maximum value calculations, statistical analysis, and threshold detection to identify when measured current values exceed predetermined safety limits. The local processing may enable rapid response to hazardous conditions without requiring communication delays with the controller board.

The method may proceed with transmitting wake-up signals from the sensor board to the controller board upon detecting threshold breaches. The wake-up signaling capability may enable the sensor board microcontroller to immediately alert the controller board when dangerous current conditions are detected. This approach may significantly reduce system response time compared to periodic polling methods while enabling power-efficient operation during normal monitoring conditions.

The method may continue with activating visual alerts using at least one light-emitting diode and audible alerts using a siren when dangerous current levels are detected. The controller board may receive the wake-up signals from the sensor board and immediately activate the visual alert components and audible alert system to provide immediate local warnings to personnel in the vicinity of the monitored area. The visual alerts may utilize programmable color patterns and brightness levels to indicate different types of hazards, while the audible alerts may generate high-intensity sound signals sufficient to alert personnel across the aquatic environment.

The method may conclude with transmitting measurement data and alert information to a remote server via a communication module. The controller board may format and transmit comprehensive data packets containing electrical current measurements, environmental sensor readings, system status information, and alert conditions to cloud-based monitoring systems. The data transmission may enable remote monitoring capabilities and provide facility operators with immediate access to hazard notifications and system status information through mobile applications and web-based dashboards.

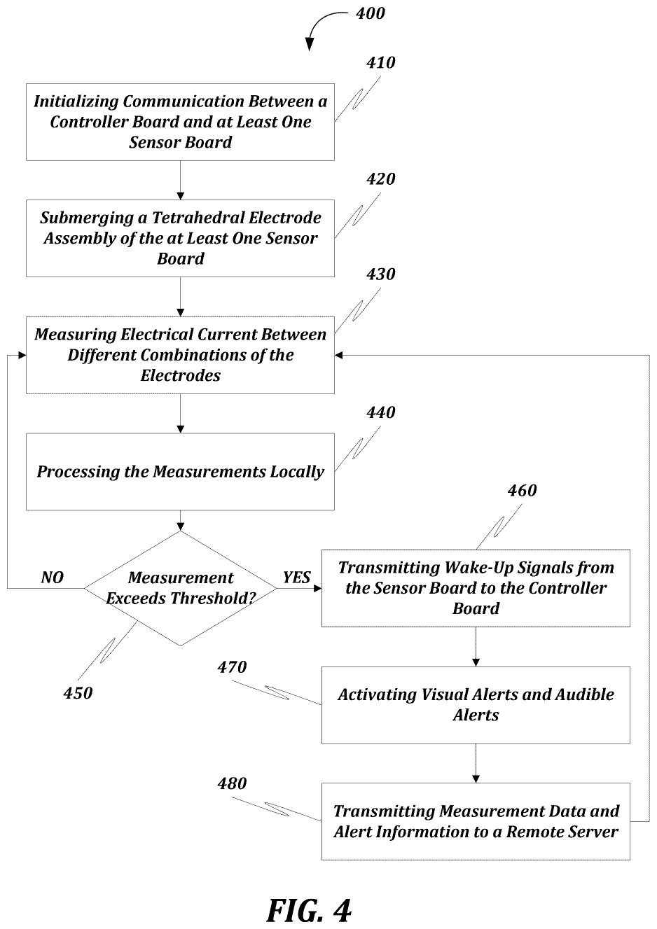

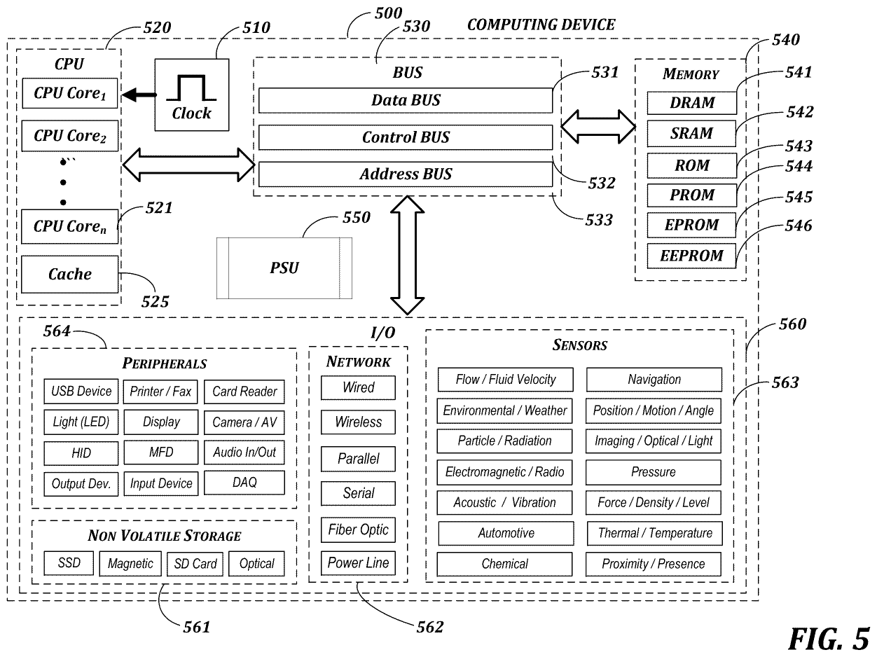

FIG. 4 is a flow chart setting forth the general stages involved in a method 400 consistent with an embodiment of the disclosure for detecting electrical current in water using a modular water current detection platform 100. Method 400 may be implemented using a computing device 500 or any other component associated with platform 100 as described in more detail below with respect to FIG. 5. For illustrative purposes alone, computing device 500 is described as one potential actor in the following stages.

Method 400 may begin at stage 410 where computing device 500 may initialize communication between the controller board 120 and at least one sensor board 102 via a digital signal network. The initialization process may establish communication protocols and network topology configurations required for coordinated operation between the distributed system components. The controller board 120 may implement automatic network discovery protocols to detect and configure sensor boards 102 when they may be connected to the digital signal network.

The digital signal network may utilize cables (e.g., CAT8 cables, twisted pair cables, etc.)that may provide both power delivery and digital communication capabilities between the controller board 120 and multiple sensor boards 102. The network initialization may include device addressing assignment to enable unique identification of each sensor board 102 within the multi-sensor network. The controller board 120 may verify connectivity status and operational readiness of each connected sensor board 102 during the initialization process.

The sensor board microcontroller 108 may execute startup procedures including self-diagnostic checks of the tetrahedral electrode assembly 106 and associated measurement circuitry. The sensor board 102 may report initial status information to the controller board 120 including power levels, electrode connectivity, and measurement circuit integrity. The galvanic isolation circuitry 110 may be verified during initialization to ensure proper electrical separation between measurement circuits and the main power supply system.

Furthermore, the system may execute periodic self-diagnostic operations to assess the health of electrodes, communication links, and electronic components. Self-testing routines may verify electrode connectivity, detect sensor degradation or fouling, and evaluate measurement circuit integrity. Detected faults or maintenance needs may be automatically reported to administrators through remote dashboards, supporting predictive maintenance and minimizing system downtime.

The initialization process may include calibration parameter loading from non-volatile memory storage within both the controller board 120 and sensor boards 102. Environmental sensor readings may be obtained during initialization to establish baseline conditions for subsequent measurement operations. The controller board 120 may configure measurement parameters, detection thresholds, and sampling rates for each connected sensor board 102 based on deployment requirements and environmental conditions.

At stage 420, the tetrahedral electrode assembly 106 of the at least one sensor board 102 may be submerged in water. The submersion process may position the four electrodes at the vertices of the tetrahedron in direct contact with the water environment to be monitored. The tetrahedral electrode assembly 106 may be deployed at predetermined depths and locations to provide optimal coverage of the monitored aquatic area.

The electrode assembly 106 may be constructed from noble metal materials such as titanium to minimize galvanic effects that could interfere with accurate current measurements in water environments. The electrodes may be spaced at calibrated distances optimized for measurement sensitivity across a range of current intensities and flow patterns that may occur in aquatic environments. Waterproof connections and cable management systems may ensure reliable electrical contact while preventing water ingress into sensitive electronic components.

The submersion process may include verification of proper electrode positioning and electrical connectivity through initial measurement cycles performed by the sensor board microcontroller 108. Temperature sensors embedded within the tetrahedral electrode assembly 106 may begin measuring local water conditions to enable automatic calibration adjustments. The sensor board 102 may report successful submersion and operational readiness to the controller board 120 through the digital communication network.

At stage 430, computing device 500 may measure electrical current between different combinations of three electrodes from the tetrahedral electrode assembly 106 to determine three-dimensional current flow patterns. The sensor board microcontroller 108 may sequentially activate different electrode combinations to construct comprehensive current flow measurements across multiple spatial planes around the sensor location.

The measurement process may utilize four combinations of three electrodes each to define measurement planes across which electrical current may be detected. Each measurement cycle may apply known voltage potentials across selected electrode pairs and measure the resulting current flow to determine water resistance between electrode combinations. The sensor board microcontroller 108 may calculate actual current flow in the water using Ohm's law relationships with the measured voltages and calculated resistances.

The electrical current sensor 104 may implement multiplexing circuitry to sequentially connect different combinations of electrodes from the tetrahedral electrode assembly 106 to the measurement circuits. Signal conditioning circuitry may apply analog filtering techniques to reduce interference from external electromagnetic sources that could affect measurement accuracy. The measurement data may be processed through analog-to-digital conversion circuitry to provide digital values for analysis by the sensor microcontroller 108.

The three-dimensional measurement capability may enable detection of current flow direction and intensity across multiple spatial planes simultaneously. The tetrahedral configuration may allow the electrode assembly 106 to detect electrical hazards occurring in complex three-dimensional water environments that traditional two-dimensional measurement approaches may fail to identify. The sensor board 102 may construct comprehensive three-dimensional current flow patterns by combining measurements from the different electrode combinations.

At stage 440, computing device 500 may process the measurements from stage 430 locally at the sensor board 102 using the sensor microcontroller 108 to detect absolute threshold breaches. The sensor microcontroller 108 may execute local signal processing algorithms including minimum and maximum value calculations, statistical analysis, and threshold detection to identify when measured current values exceed predetermined safety limits.

The local processing capability may enable rapid response to hazardous conditions without requiring communication delays with the controller board 120. The sensor microcontroller 108 may perform cyclic redundancy check computations to ensure data integrity during local processing operations. Statistical parameters including mean values, standard deviations, and variance measurements may be calculated to characterize the electrical environment around the sensor location.

The sensor microcontroller 108 may implement rate of change analysis algorithms to predict hazardous conditions before critical thresholds are exceeded. The time derivative of current measurements may be calculated to identify rapidly increasing current levels that may indicate developing electrical hazards. Predictive algorithms may estimate future current levels based on observed trends in the measurement data.

Temperature compensation algorithms may be applied to correct electrical current measurements for variations in water temperature that affect conductivity. The sensor microcontroller 108 may process temperature sensor data from the embedded temperature sensors within the tetrahedral electrode assembly 106. Correction factors may be calculated based on temperature measurements to maintain measurement accuracy across seasonal temperature variations.

Digital filtering techniques may be applied to reduce interference from external electromagnetic sources that could affect measurement accuracy. The sensor microcontroller 108 may implement pattern recognition algorithms to identify characteristic signatures of electrical hazards versus natural electrical phenomena in aquatic environments. Differential calculation algorithms may distinguish actual current leakage from environmental electrical noise and galvanic effects.

At stage 450, computing device 500 may continue with transmitting wake-up signals from the sensor board 102 to the controller board 120, in response to detecting threshold breaches. The wake-up signaling capability may enable the sensor board microcontroller 108 to alert the controller board 120 when dangerous electrical current conditions are detected at the sensor location.

The wake-up signal transmission may utilize the digital communication network established between the sensor board 102 and controller board 120. Priority-based message handling may ensure that wake-up signals receive immediate transmission precedence over routine measurement data. The sensor board 102 may implement collision detection and avoidance protocols to prevent data corruption when multiple sensor boards 102 may attempt simultaneous wake-up signal transmission.

The wake-up signaling approach may significantly reduce system response time compared to periodic polling methods while enabling power-efficient operation during normal monitoring conditions. The controller board microcontroller 122 may immediately activate from power-saving modes upon receiving wake-up signals to ensure rapid system response to electrical hazards. The controller board 120 may coordinate with sensor board microcontrollers 108 to verify hazard conditions and initiate appropriate safety responses.

Error detection and correction protocols may ensure reliable wake-up signal transmission across the digital communication network. The sensor board 102 may retransmit wake-up signals if acknowledgment is not received from the controller board 120 within predetermined time intervals. Network addressing capabilities may enable the controller board 120 to identify which specific sensor board 102 generated the wake-up signal when multiple sensor boards 102 are connected to the network.

At stage 460, the computing device 500 may activate visual alerts using at least one light-emitting diode 128 and/or audible alerts using a siren 130 responsive to detection of dangerous electrical current levels. The controller board 120 may receive wake-up signals from sensor boards 102 and immediately activate the visual alert components 128 and audible alert system 130 to provide immediate local warnings to personnel in the vicinity of the monitored area.

The light-emitting diodes of the visual alert components 128 may generate high-intensity visual alerts with brightness levels that may enable visibility across various lighting conditions encountered in aquatic environments. RGBW light-emitting diodes may provide red, green, blue, and white color capabilities for generating distinct alert patterns based on detected hazard conditions. The visual alert components 128 may implement programmable color patterns that may correspond to different types of electrical hazards detected by the sensor boards 102.

The controller board microcontroller 122 may control the visual alert components 128 through digital signal interfaces that may enable precise control of color selection, brightness levels, and timing patterns for the light-emitting diodes. Solid color displays may be generated for steady-state hazard conditions while flashing patterns may indicate critical alert conditions that may require immediate attention from personnel. Different colors may be displayed simultaneously to convey multiple types of status information including system operational status and hazard severity levels.

The siren 130 may generate high-intensity audible alerts when dangerous electrical current conditions are detected in the monitored water area. The siren 130 may produce sound output with sufficient acoustic power to alert personnel across the aquatic environment and surrounding areas. Sound intensity levels may reach approximately 100 decibels or more measured at a standard distance from the device to ensure audible alerts are clearly audible to personnel operating in the vicinity.

The siren 130 may generate multiple distinct sound patterns that may correspond to different types of electrical hazards detected by the sensor boards 102. Continuous tone alerts may be produced for steady-state hazard conditions while intermittent or pulsed tone patterns may indicate critical alert conditions. The controller board microcontroller 122 may control the siren 130 through digital signal interfaces that may enable precise control of sound pattern selection, volume levels, and timing sequences.

At stage 470, computing device 500 may transmit measurement data and alert information to a remote server via a communication module 132. The controller board 120 may format and transmit comprehensive data packets containing electrical current measurements from connected sensor boards 102, environmental sensor readings, system operational status, power source conditions, and alert conditions to cloud-based monitoring systems.

The communication module 132 may implement multiple wireless communication protocols to ensure reliable connectivity across diverse deployment environments. Cellular communication standards including fourth generation long term evolution and fifth generation wireless protocols may enable data transmission in areas where other wireless networks may not be available. Wi-Fi connectivity may be utilized as the primary communication method when available with automatic switching to cellular communication when Wi-Fi networks are unavailable or unreliable. Additionally or alternatively, the system may utilize WPAN protocols, such as Bluetooth, Zigbee, etc. for communication.

Data buffering capabilities may store measurement data and system status information during periods when wireless communication links are unavailable. Local memory storage within the controller board 120 may maintain measurement records until communication connectivity is restored. Data compression algorithms may optimize bandwidth utilization and reduce data transmission costs when using cellular communication networks.

The communication module 132 may support bidirectional communication to enable both data transmission from the controller board 120 to remote servers and command reception from remote monitoring systems. Configuration updates, firmware upgrade commands, and operational parameter adjustments may be received from cloud-based management systems. Authentication and encryption protocols may ensure secure data transmission and prevent unauthorized access to system functions.

The transmitted data may include electrical current measurements, environmental sensor readings including temperature and humidity, system operational status, power source conditions including battery charge levels and solar panel output, alert notifications and alarm conditions, GPS positioning data when available, and device connectivity status for each connected sensor board 102. Timestamp synchronization capabilities may ensure accurate temporal correlation of measurement data across multiple deployed systems.

The data transmission may enable remote monitoring capabilities and may provide facility operators with immediate access to hazard notifications and system status information through mobile applications and web-based dashboards. Real-time streaming may be implemented for critical alert conditions while periodic batch transmission may be utilized for routine measurement data. Priority-based message handling may ensure immediate transmission of hazard alerts while queuing routine status information for transmission during optimal communication conditions.

The platform may further comprise automated compliance and regulatory reporting functionality. Measurement logs, incident records, and power quality data may be maintained in secure, tamper-evident storage and periodically transmitted to designated authorities or insurance providers. The system may generate digital compliance certificates, safety audit reports, and support standardized electronic submission to municipal, state, or insurer databases as required by applicable regulations.

### IV. Hardware Architecture

Embodiments of the present disclosure provide a hardware and software platform operative as a distributed system of modules and computing elements.

Platform 100 may be embodied as, for example, but not be limited to, a website, a web application, a desktop application, a backend application, and a mobile application compatible with a computing device 500. The computing device 500 may comprise, but not be limited to, the following:
Mobile computing device, such as, but is not limited to, a laptop, a tablet, a smartphone, a drone, a wearable, an embedded device, a handheld device, an Arduino, an industrial device, or a remotely operable recording device;
A supercomputer, an exascale supercomputer, a mainframe, or a quantum computer;
A minicomputer, wherein the minicomputer computing device comprises, but is not limited to, an IBM AS400/iSeries/System I, A DEC VAX/PDP, an HP3000, a Honeywell-Bull DPS, a Texas Instruments TI-990, or a Wang Laboratories VS Series;
A microcomputer, wherein the microcomputer computing device comprises, but is not limited to, a server, wherein a server may be rack-mounted, a workstation, an industrial device, a raspberry pi, a desktop, or an embedded device;

Platform 100 may be hosted on a centralized server or a cloud computing service. Although method 400 has been described to be performed by a computing device 500, it should be understood that, in some embodiments, different operations may be performed by a plurality of the computing devices 500 in operative communication on at least one network.

Embodiments of the present disclosure may comprise a system having a central processing unit (CPU) 520, a bus 530, a memory unit 540, a power supply unit (PSU) 550, and one or more Input/Output (I/O) units. The CPU 520 coupled to the memory unit 540 and the plurality of I/O units 560 via the bus 530, all of which are powered by the PSU 550. It should be understood that, in some embodiments, each disclosed unit may actually be a plurality of such units for redundancy, high availability, and/or performance purposes. The combination of the presently disclosed units is configured to perform the stages of any method disclosed herein.

FIG. 5 is a block diagram of a system including computing device 500. Consistent with an embodiment of the disclosure, the aforementioned CPU 520, the bus 530, the memory unit 540, a PSU 550, and the plurality of I/O units 560 may be implemented in a computing device, such as computing device 500 of FIG. 5. Any suitable combination of hardware, software, or firmware may be used to implement the aforementioned units. For example, the CPU 520, the bus 530, and the memory unit 540 may be implemented with computing device 500 or any of other computing devices 500, in combination with computing device 500. The aforementioned system, device, and components are examples and other systems, devices, and components may comprise the aforementioned CPU 520, the bus 530, and the memory unit 540, consistent with embodiments of the disclosure.

At least one computing device 500 may be embodied as any of the computing elements illustrated in all of the attached figures. A computing device 500 does not need to be electronic, nor even have a CPU 520, nor bus 530, nor memory unit 540. The definition of the computing device 500 to a person having ordinary skill in the art is “A device that computes, especially a programmable [usually] electronic machine that performs high-speed mathematical or logical operations or that assembles, stores, correlates, or otherwise processes information.” Any device which processes information qualifies as a computing device 500, especially if the processing is purposeful.

With reference to FIG. 5, a system consistent with an embodiment of the disclosure may include a computing device, such as computing device 500. In some configurations, the computing device 500 may include at least one clock module 510, at least one CPU 520, at least one bus 530, and at least one memory unit 540, at least one PSU 550, and at least one I/O 560 module, wherein I/O module may be comprised of, but not limited to a non-volatile storage sub-module 561, a communication sub-module 562, a sensors sub-module 563, and a peripherals sub-module 564.

In a system consistent with an embodiment of the disclosure, the computing device 500 may include the clock module 510, known to a person having ordinary skill in the art as a clock generator, which produces clock signals. Clock signals may oscillate between a high state and a low state at a controllable rate, and may be used to synchronize or coordinate actions of digital circuits. Most integrated circuits (ICs) of sufficient complexity use a clock signal in order to synchronize different parts of the circuit, cycling at a rate slower than the worst-case internal propagation delays. One well-known example of the aforementioned integrated circuit is the CPU 520, the central component of modern computers, which relies on a clock signal. The clock 510 can comprise a plurality of embodiments, such as, but not limited to, a single-phase clock which transmits all clock signals on effectively 1 wire, a two-phase clock which distributes clock signals on two wires, each with non-overlapping pulses, and a four-phase clock which distributes clock signals on 4 wires.

Many computing devices 500 may use a “clock multiplier” which multiplies a lower frequency external clock to the appropriate clock rate of the CPU 520. This allows the CPU 520 to operate at a much higher frequency than the rest of the computing device 500, which affords performance gains in situations where the CPU 520 does not need to wait on an external factor (like memory 540 or input/output 560). Some embodiments of the clock 510 may include dynamic frequency change, where the time between clock edges can vary widely from one edge to the next and back again.

In a system consistent with an embodiment of the disclosure, the computing device 500 may include the CPU 520 comprising at least one CPU Core 521. In other embodiments, the CPU 520 may include a plurality of identical CPU cores 521, such as, but not limited to, homogeneous multi-core systems. It is also possible for the plurality of CPU cores 521 to comprise different CPU cores 521, such as, but not limited to, heterogeneous multi-core systems, big. LITTLE systems and some AMD accelerated processing units (APU). The CPU 520 reads and executes program instructions which may be used across many application domains, for example, but not limited to, general purpose computing, embedded computing, network computing, digital signal processing (DSP), and graphics processing (GPU). The CPU 520 may run multiple instructions on separate CPU cores 521 simultaneously. The CPU 520 may be integrated into at least one of a single integrated circuit die, and multiple dies in a single chip package. The single integrated circuit die and/or the multiple dies in a single chip package may contain a plurality of other elements of the computing device 500, for example, but not limited to, the clock 510, the bus 530, the memory 540, and I/O 560.

The CPU 520 may contain cache 522 such as but not limited to a level 1 cache, a level 2 cache, a level 3 cache, or combinations thereof. The cache 522 may or may not be shared amongst a plurality of CPU cores 521. The cache 522 sharing may comprise at least one of message passing and inter-core communication methods used for the at least one CPU Core 521 to communicate with the cache 522. The inter-core communication methods may comprise, but not be limited to, bus, ring, two-dimensional mesh, and crossbar. The aforementioned CPU 520 may employ symmetric multiprocessing (SMP) design.

The one or more CPU cores 521 may comprise soft microprocessor cores on a single field programmable gate array (FPGA), such as semiconductor intellectual property cores (IP Core). The architectures of the one or more CPU cores 521 may be based on at least one of, but not limited to, Complex Instruction Set Computing (CISC), Zero Instruction Set Computing (ZISC), and Reduced Instruction Set Computing (RISC). At least one performance-enhancing method may be employed by one or more of the CPU cores 521, for example, but not limited to Instruction-level parallelism (ILP) such as, but not limited to, superscalar pipelining, and Thread-level parallelism (TLP).

Consistent with the embodiments of the present disclosure, the aforementioned computing device 500 may employ a communication system that transfers data between components inside the computing device 500, and/or the plurality of computing devices 500. The aforementioned communication system will be known to a person having ordinary skill in the art as a bus 530. The bus 530 may embody internal and/or external hardware and software components, for example, but not limited to a wire, an optical fiber, various communication protocols, and/or any physical arrangement that provides the same logical function as a parallel electrical bus. The bus 530 may comprise at least one of a parallel bus, wherein the parallel bus carries data words in parallel on multiple wires; and a serial bus, wherein the serial bus carries data in bit-wise serial form. The bus 530 may embody a plurality of topologies, for example, but not limited to, a multidrop/electrical parallel topology, a daisy chain topology, and connected by switched hubs, such as a USB bus. The bus 530 may comprise a plurality of embodiments, for example, but not limited to:
Internal data bus (data bus) 531/Memory bus
Control bus 532
Address bus 533
System Management Bus (SMBus)
Front-Side-Bus (FSB)
External Bus Interface (EBI)
Local bus
Expansion bus
Lightning bus
Controller Area Network (CAN bus)
Camera Link
ExpressCard
Advanced Technology management Attachment (ATA), including embodiments and derivatives such as, but not limited to, Integrated Drive Electronics (IDE)/Enhanced IDE (EIDE), ATA Packet Interface (ATAPI), Ultra-Direct Memory Access (UDMA), Ultra ATA (UATA)/Parallel ATA (PATA)/Serial ATA (SATA), CompactFlash (CF) interface, Consumer Electronics ATA (CE-ATA)/Fiber Attached Technology Adapted (FATA), Advanced Host Controller Interface (AHCI), SATA Express (SATAe)/External SATA (eSATA), including the powered embodiment eSATAp/Mini-SATA (mSATA), and Next Generation Form Factor (NGFF)/M.2.
Small Computer System Interface (SCSI)/Serial Attached SCSI (SAS)
HyperTransport
InfiniBand
RapidIO
Mobile Industry Processor Interface (MIPI)
Coherent Processor Interface (CAPI)
Plug-n-play
1-Wire
Peripheral Component Interconnect (pci), Including

embodiments such as but not limited to, Accelerated Graphics Port (AGP), Peripheral Component Interconnect eXtended (PCI-X), Peripheral Component Interconnect Express (PCI-e) (e.g., PCI Express Mini Card, PCI Express M.2 [Mini PCIe v2], PCI Express External Cabling [ePCIe], and PCI Express OCuLink [Optical Copper{Cu} Link]), Express Card, AdvancedTCA, AMC, Universal IO, Thunderbolt/Mini DisplayPort, Mobile PCIe (M-PCIe), U.2, and Non-Volatile Memory Express (NVMe)/Non-Volatile Memory Host Controller Interface Specification (NVMHCIS).
Industry Standard Architecture (isa), including embodiments such as, but not limited to Extended ISA (EISA), PC/XT-bus/PC/AT-bus/PC/104 bus (e.g., PC/104-Plus, PCI/104-Express, PCI/104, and PCI-104), and Low Pin Count (LPC).
Music Instrument Digital Interface (MIDI)
Universal Serial Bus (USB), including embodiments such as, but not limited to, Media Transfer Protocol (MTP)/Mobile High-Definition Link (MHL), Device Firmware Upgrade (DFU), wireless USB, InterChip USB, IEEE 1394 Interface/Firewire, Thunderbolt, and eXtensible Host Controller Interface (xHCI).

Consistent with the embodiments of the present disclosure, the aforementioned computing device 500 may employ hardware integrated circuits that store information for immediate use in the computing device 500, known to persons having ordinary skill in the art as primary storage or memory 540. The memory 540 operates at high speed, distinguishing it from the non-volatile storage sub-module 561, which may be referred to as secondary or tertiary storage, which provides relatively slower-access to information but offers higher storage capacity. The data contained in memory 540, may be transferred to secondary storage via techniques such as, but not limited to, virtual memory and swap. The memory 540 may be associated with addressable semiconductor memory, such as integrated circuits consisting of silicon-based transistors, that may be used as primary storage or for other purposes in the computing device 500. The memory 540 may comprise a plurality of embodiments, such as, but not limited to volatile memory, non-volatile memory, and semi-volatile memory. It should be understood by a person having ordinary skill in the art that the following are non-limiting examples of the aforementioned memory:
Volatile memory, which requires power to maintain stored information, for example, but not limited to, Dynamic Random-Access Memory (DRAM) 541, Static Random-Access Memory (SRAM) 542, CPU Cache memory 525, Advanced Random-Access Memory (A-RAM), and other types of primary storage such as Random-Access Memory (RAM).
Non-volatile memory, which can retain stored information even after power is removed, for example, but not limited to, Read-Only Memory (ROM) 543, Programmable ROM (PROM) 544, Erasable PROM (EPROM) 545, Electrically Erasable PROM (EEPROM) 546 (e.g., flash memory and Electrically Alterable PROM [EAPROM]), Mask ROM (MROM), One Time Programmable (OTP) ROM/Write Once Read Many (WORM), Ferroelectric RAM (FeRAM), Parallel Random-Access Machine (PRAM), Split-Transfer Torque RAM (STT-RAM), Silicon Oxime Nitride Oxide Silicon (SONOS), Resistive RAM (RRAM), Nano RAM (NRAM), 3D XPoint, Domain-Wall Memory (DWM), and millipede memory.
Semi-volatile memory may have limited non-volatile duration after power is removed but may lose data after said duration has passed. Semi-volatile memory provides high performance, durability, and other valuable characteristics typically associated with volatile memory, while providing some benefits of true non-volatile memory. The semi-volatile memory may comprise volatile and non-volatile memory, and/or volatile memory with a battery to provide power after power is removed. The semi-volatile memory may comprise, but is not limited to, spin-transfer torque RAM (STT-RAM).

Consistent with the embodiments of the present disclosure, the aforementioned computing device 500 may employ a communication system between an information processing system, such as the computing device 500, and the outside world, for example, but not limited to, human, environment, and another computing device 500. The aforementioned communication system may be known to a person having ordinary skill in the art as an Input/Output (I/O) module 560. The I/O module 560 regulates

a plurality of inputs and outputs with regard to the computing device 500,

wherein the inputs are a plurality of signals and data received by the

computing device 500, and the outputs are the plurality of signals and data sent from the computing device 500. The I/O module 560 interfaces with a plurality of hardware, such as, but not limited to, non-volatile storage 561, communication devices 562, sensors 563, and peripherals 564. The plurality of hardware is used by at least one of, but not limited to, humans, the environment, and another computing device 500 to communicate with the present computing device 500. The I/O module 560 may comprise a plurality of forms, for example, but not limited to channel I/O, port mapped I/O, asynchronous I/O, and Direct Memory Access (DMA).

Consistent with the embodiments of the present disclosure, the aforementioned computing device 500 may employ a non-volatile storage sub-module 561, which may be referred to by a person having ordinary skill in the art as one of secondary storage, external memory, tertiary storage, off-line storage, and auxiliary storage. The non-volatile storage sub-module 561 may not be accessed directly by the CPU 520 without using an intermediate area in the memory 540. The non-volatile storage sub-module 561 may not lose data when power is removed and may be orders of magnitude less costly than storage used in memory 540. Further, the non-volatile storage sub-module 561 may have a slower speed and higher latency than in other areas of the computing device 500. The non-volatile storage sub-module 561 may comprise a plurality of forms, such as, but not limited to, Direct Attached Storage (DAS), Network Attached Storage (NAS), Storage Area Network (SAN), nearline storage, Massive Array of Idle Disks (MAID), Redundant Array of Independent Disks (RAID), device mirroring, off-line storage, and robotic storage. The non-volatile storage sub-module (561) may comprise a plurality of embodiments, such as, but not limited to:
Optical storage, for example, but not limited to, Compact Disk (CD) (CD-ROM/CD-R/CD-RW), Digital Versatile Disk (DVD) (DVD-ROM/DVD-R/DVD+R/DVD-RW/DVD+RW/DVD±RW/DVD+R DL/DVD-RAM/HD-DVD), Blu-ray Disk (BD) (BD-ROM/BD-R/BD-RE/BD-R DL/BD-RE DL), and Ultra-Density Optical (UDO).
Semiconductor storage, for example, but not limited to, flash memory, such as, but not limited to, USB flash drive, Memory card, Subscriber Identity Module (SIM) card, Secure Digital (SD) card, Smart Card, CompactFlash (CF) card, Solid-State Drive (SSD) and memristor.
Magnetic storage such as, but not limited to, Hard Disk Drive (HDD), tape drive, carousel memory, and Card Random-Access Memory (CRAM).
Phase-change memory
Holographic data storage such as Holographic Versatile Disk (HVD).
Molecular Memory
Deoxyribonucleic Acid (DNA) digital data storage

Consistent with the embodiments of the present disclosure, the computing device 500 may employ a communication sub-module 562 as a subset of the I/O module 560, which may be referred to by a person having ordinary skill in the art as at least one of, but not limited to, a computer network, a data network, and a network. The network may allow computing devices 500 to exchange data using connections, which may also be known to a person having ordinary skill in the art as data links, which may include data links between network nodes. The nodes may comprise networked computer devices 500 that may be configured to originate, route, and/or terminate data. The nodes may be identified by network addresses and may include a plurality of hosts consistent with the embodiments of a computing device 500. Examples of computing devices that may include a communication sub-module 562 include, but are not limited to, personal computers, phones, servers, drones, and networking devices such as, but not limited to, hubs, switches, routers, modems, and firewalls.

Two nodes can be considered networked together when one computing device 500 can exchange information with the other computing device 500, regardless of any direct connection between the two computing devices 500. The communication sub-module 562 supports a plurality of applications and services, such as, but not limited to World Wide Web (WWW), digital video and audio, shared use of application and storage computing devices 500, printers/scanners/fax machines, email/online chat/instant messaging, remote control, distributed computing, etc. The network may comprise one or more transmission mediums, such as, but not limited to conductive wire, fiber optics, and wireless signals. The network may comprise one or more communications protocols to organize network traffic, wherein application-specific communications protocols may be layered, and may be known to a person having ordinary skill in the art as being improved for carrying a specific type of payload, when compared with other more general communications protocols. The plurality of communications protocols may comprise, but are not limited to, IEEE 802, ethernet, Wireless LAN (WLAN/Wi-Fi), Internet Protocol (IP) suite (e.g., TCP/IP, UDP, Internet Protocol version 4 [IPv4], and Internet Protocol version 6[IPv6 ]), Synchronous Optical Networking (SONET)/Synchronous Digital Hierarchy (SDH), Asynchronous Transfer Mode (ATM), and cellular standards (e.g., Global System for Mobile Communications [GSM], General Packet Radio Service [GPRS], Code-Division Multiple Access [CDMA], Integrated Digital Enhanced Network [IDEN], Long Term Evolution [LTE], LTE-Advanced [LTE-A], and fifth generation [5G] communication protocols). The communication sub-module 562 may comprise a plurality of size, topology, traffic control mechanisms and organizational intent policies. The communication sub-module 562 may comprise a plurality of embodiments, such as, but not limited to:
Wired communications, such as, but not limited to, coaxial cable, phone lines, twisted pair cables (ethernet), and InfiniBand.
Wireless communications, such as, but not limited to, communications satellites, cellular systems, radio frequency/spread spectrum technologies, IEEE 802.11 Wi-Fi, Bluetooth, NFC, free-space optical communications, terrestrial microwave, and Infrared (IR) communications. Wherein cellular systems embody technologies such as, but not limited to, 3G,4G (such as WiMAX and LTE), and 5G (short and long wavelength).
Parallel communications, such as, but not limited to, LPT ports.
Serial communications, such as, but not limited to, RS-232 and USB.
Fiber Optic communications, such as, but not limited to, Single-mode optical fiber (SMF) and Multi-mode optical fiber (MMF).
Power Line communications

The aforementioned network may comprise a plurality of layouts, such as, but not limited to, bus networks such as Ethernet, star networks such as Wi-Fi, ring networks, mesh networks, fully connected networks, and tree networks. The network can be characterized by its physical capacity or its organizational purpose. Use of the network, including user authorization and access rights, may differ according to the layout of the network. The characterization may include, but is not limited to a nanoscale network, a Personal Area Network (PAN), a Local Area Network (LAN), a Home Area Network (HAN), a Storage Area Network (SAN), a Campus Area Network (CAN), a backbone network, a Metropolitan Area Network (MAN), a Wide Area Network (WAN), an enterprise private network, a Virtual Private Network (VPN), and a Global Area Network (GAN).

Consistent with the embodiments of the present disclosure, the aforementioned computing device 500 may employ a sensors sub-module 563 as a subset of the I/O 560. The sensors sub-module 563 comprises at least one of the device, module, or subsystem whose purpose is to detect events or changes in its environment and send the information to the computing device 500. Sensors may be sensitive to the property they are configured to measure, may not be sensitive to any property not measured but be encountered in its application, and may not significantly influence the measured property. The sensors sub-module 563 may comprise a plurality of digital devices and analog devices, wherein if an analog device is used, an Analog to Digital (A-to-D) converter must be employed to interface the said device with the computing device 500. The sensors may be subject to a plurality of deviations that limit sensor accuracy. The sensors sub-module 563 may comprise a plurality of embodiments, such as, but not limited to, chemical sensors, automotive sensors, acoustic/sound/vibration sensors, electric current/electric potential/magnetic/radio sensors, environmental/weather/moisture/humidity sensors, flow/fluid velocity sensors, ionizing radiation/particle sensors, navigation sensors, position/angle/displacement/distance/speed/acceleration sensors, imaging/optical/light sensors, pressure sensors, force/density/level sensors, thermal/temperature sensors, and proximity/presence sensors. It should be understood by a person having ordinary skill in the art that the ensuing are non-limiting examples of the aforementioned sensors:
Chemical sensors, such as, but not limited to, breathalyzer, carbon dioxide sensor, carbon monoxide/smoke detector, catalytic bead sensor, chemical field-effect transistor, chemiresistor, electrochemical gas sensor, electronic nose, electrolyte-insulator- semiconductor sensor, energy-dispersive X-ray spectroscopy, fluorescent chloride sensors, holographic sensor, hydrocarbon dew point analyzer, hydrogen sensor, hydrogen sulfide sensor, infrared point sensor, ion-selective electrode, nondispersive infrared sensor, microwave chemistry sensor, nitrogen oxide sensor, olfactometer, optode, oxygen sensor, ozone monitor, pellistor, pH glass electrode, potentiometric sensor, redox electrode, zinc oxide nanorod sensor, and biosensors (such as nanosensors).
Automotive sensors, such as, but not limited to, air flow meter/mass airflow sensor, air-fuel ratio meter, AFR sensor, blind spot monitor, engine coolant/exhaust gas/cylinder head/transmission fluid temperature sensor, hall effect sensor, wheel/automatic transmission/turbine/vehicle speed sensor, airbag sensors, brake fluid/engine crankcase/fuel/oil/tire pressure sensor, camshaft/crankshaft/throttle position sensor, fuel/oil level sensor, knock sensor, light sensor, MAP sensor, oxygen sensor (o2), parking sensor, radar sensor, torque sensor, variable reluctance sensor, and water-in-fuel sensor.
Acoustic, sound and vibration sensors, such as, but not limited to, microphone, lace sensors such as a guitar pickup, seismometer, sound locator, geophone, and hydrophone.
Electric current, electric potential, magnetic, and radio sensors, such as, but not limited to, current sensor, Daly detector, electroscope, electron multiplier, faraday cup, galvanometer, hall effect sensor, hall probe, magnetic anomaly detector, magnetometer, magnetoresistance, MEMS magnetic field sensor, metal detector, planar hall sensor, radio direction finder, and voltage detector.
Environmental, weather, moisture, and humidity sensors,

such as, but not limited to, actinometer, air pollution sensor, moisture alarm, ceilometer, dew warning, electrochemical gas sensor, fish counter, frequency domain sensor, gas detector, hook gauge evaporimeter, humistor, hygrometer, leaf sensor, lysimeter, pyranometer, pyrgeometer, psychrometer, rain gauge, rain sensor, seismometers, SNOTEL, snow gauge, soil moisture sensor, stream gauge, and tide gauge.
Flow and fluid velocity sensors, such as, but not limited to, air flow meter, anemometer, flow sensor, gas meter, mass flow sensor, and water meter.
Ionizing radiation and particle sensors, such as, but not limited to, cloud chamber, Geiger counter, Geiger-Muller tube, ionization chamber, neutron detection, proportional counter, scintillation counter, semiconductor detector, and thermoluminescent dosimeter.
Navigation sensors, such as, but not limited to, airspeed indicator, altimeter, attitude indicator, depth gauge, fluxgate compass, gyroscope, inertial navigation system, inertial reference unit, magnetic compass, MHD sensor, ring laser gyroscope, turn coordinator, variometer, vibrating structure gyroscope, and yaw rate sensor.
Position, angle, displacement, distance, speed, and acceleration sensors, such as but not limited to, accelerometer, displacement sensor, flex sensor, free-fall sensor, gravimeter, impact sensor, laser rangefinder, LIDAR, odometer, photoelectric sensor, position sensor such as, but not limited to, GPS or Glonass, angular rate sensor, shock detector, ultrasonic sensor, tilt sensor, tachometer, ultra-wideband radar, variable reluctance sensor, and velocity receiver.
Imaging, optical and light sensors, such as, but not limited to, CMOS sensor, colorimeter, contact image sensor, electro-optical sensor, infra-red sensor, kinetic inductance detector, LED configured as a light sensor, light-addressable potentiometric sensor, Nichols radiometer, fiber-optic sensors, optical position sensor, thermopile laser sensor, photodetector, photodiode, photomultiplier tubes, phototransistor, photoelectric sensor, photoionization detector, photomultiplier, photoresistor, photoswitch, phototube, scintillometer, Shack-Hartmann, single-photon avalanche diode, superconducting nanowire single-photon detector, transition edge sensor, visible light photon counter, and wavefront sensor.
Pressure sensors, such as, but not limited to, barograph, barometer, boost gauge, bourdon gauge, hot filament ionization gauge, ionization gauge, McLeod gauge, Oscillating U-tube, permanent downhole gauge, piezometer, Pirani gauge, pressure sensor, pressure gauge, tactile sensor, and time pressure gauge.
Force, Density, and Level sensors, such as, but not limited to, bhangmeter, hydrometer, force gauge or force sensor, level sensor, load cell, magnetic level or nuclear density sensor or strain gauge, piezocapacitive pressure sensor, piezoelectric sensor, torque sensor, and viscometer.
Thermal and temperature sensors, such as, but not limited to, bolometer, bimetallic strip, calorimeter, exhaust gas temperature gauge, flame detection/pyrometer, Gardon gauge, Golay cell, heat flux sensor, microbolometer, microwave radiometer, net radiometer, infrared/quartz/resistance thermometer, silicon bandgap temperature sensor, thermistor, and thermocouple.
Proximity and presence sensors, such as, but not limited to, alarm sensor, doppler radar, motion detector, occupancy sensor, proximity sensor, passive infrared sensor, reed switch, stud finder, triangulation sensor, touch switch, and wired glove.

Consistent with the embodiments of the present disclosure, the aforementioned computing device 500 may employ a peripherals sub-module 564 as a subset of the I/O 560. The peripheral sub-module 564 comprises ancillary devices used to put information into and get information out of the computing device 500. There are 3 categories of devices comprising the peripheral sub-module 564, which exist based on their relationship with the computing device 500, input devices, output devices, and input/output devices. Input devices send at least one of data and instructions to the computing device 500. Input devices can be categorized based on, but not limited to:
Modality of input, such as, but not limited to, mechanical motion, audio, visual, and tactile.
Whether the input is discrete, such as but not limited to, pressing a key, or continuous such as, but not limited to the position of a mouse.
The number of degrees of freedom involved, such as, but not limited to, two-dimensional mice and three-dimensional mice used for Computer-Aided Design (CAD) applications.

Output devices provide output from the computing device 500. Output devices convert electronically generated information into a form that can be presented to humans. Input/output devices perform that perform both input and output functions. It should be understood by a person having ordinary skill in the art that the ensuing are non-limiting embodiments of the aforementioned peripheral sub-module 564:
Input Devices
   Human Interface Devices (HID), such as, but not limited to, pointing device (e.g., mouse, touchpad, joystick, touchscreen, game controller/gamepad, remote, light pen, light gun, infrared remote, jog dial, shuttle, and knob), keyboard, graphics tablet, digital pen, gesture recognition devices, magnetic ink character recognition, Sip-and-Puff (SNP) device, and Language Acquisition Device (LAD).
   High degree of freedom devices, that require up to six degrees of freedom such as, but not limited to, camera gimbals, Cave Automatic Virtual Environment (CAVE), and virtual reality systems.
   Video Input devices are used to digitize images or video from the outside world into the computing device 500. The information can be stored in a multitude of formats depending on the user's requirement. Examples of types of video input devices include, but are not limited to, digital camera, digital camcorder, portable media player, webcam, Microsoft Kinect, image scanner, fingerprint scanner, barcode reader, 3D scanner, laser rangefinder, eye gaze tracker, computed tomography, magnetic resonance imaging, positron emission tomography, medical ultrasonography, TV tuner, and iris scanner.
   Audio input devices are used to capture sound. In some cases, an audio output device can be used as an input device to capture produced sound. Audio input devices allow a user to send audio signals to the computing device 500 for at least one of processing, recording, and carrying out commands. Devices such as microphones allow users to speak to the computer to record a voice message or navigate software. Aside from recording, audio input devices are also used with speech recognition software. Examples of types of audio input devices include, but not limited to microphone, Musical Instrumental Digital Interface (MIDI) devices such as, but not limited to a keyboard, and headset.
   Data AcQuisition (DAQ) devices convert at least one of analog signals and physical parameters to digital values for processing by the computing device 500. Examples of DAQ devices may include, but not limited to, Analog to Digital Converter (ADC), data logger, signal conditioning circuitry, multiplexer, and Time to Digital Converter (TDC).
Output Devices may further comprise, but not be limited to:
   Display devices may convert electrical information into visual form, such as, but not limited to, monitor, TV, projector, and Computer Output Microfilm (COM). Display devices can use a plurality of underlying technologies, such as, but not limited to, Cathode-Ray Tube (CRT), Thin-Film Transistor (TFT), Liquid Crystal Display (LCD), Organic Light-Emitting Diode (OLED), MicroLED, E Ink Display (ePaper) and Refreshable Braille Display (Braille Terminal).
   Printers, such as, but not limited to, inkjet printers, laser printers, 3D printers, solid ink printers, and plotters.
   Audio and Video (AV) devices, such as, but not limited to, speakers, headphones, amplifiers, and lights, which include lamps, strobes, DJ lighting, stage lighting, architectural lighting, special effect lighting, and lasers.
   Other devices such as Digital to Analog Converter (DAC)
Input/Output Devices may further comprise, but not be limited to, touchscreens, networking devices (e.g., devices disclosed in network sub-module 562), data storage devices (non-volatile storage 561), facsimile (FAX), and graphics/sound cards.

All rights, including copyrights in the code included herein, are vested in and the property of the Applicant. The Applicant retains and reserves all rights in the code included herein and grants permission to reproduce the material only in connection with the reproduction of the granted patent and for no other purpose. While the specification includes examples, the disclosure's scope is indicated by the following claims. Furthermore, while the specification has been described in language specific to structural features and/or methodological acts, the claims are not limited to the features or acts described above. Rather, the specific features and acts described above are disclosed as examples for embodiments of the disclosure.

Insofar as the description above and the accompanying drawing disclose any additional subject matter that is not within the scope of the claims below, the disclosures are not dedicated to the public and the right to file one or more applications to claims such additional disclosures is reserved.

1. A water current detection system, comprising:
a controller board comprising:
a microcontroller configured to process digital signals;
a display configured to show status information;
at least one light-emitting diode configured to generate visual alerts;
a siren configured to generate audible alerts;
at least one button configured to receive user input; and
a communication module configured to transmit data to a remote server;
at least one sensor board communicatively coupled to the controller board, the at least one sensor board comprising:
a tetrahedral electrode assembly configured to be submerged in water and measure electrical current in three-dimensional space;
a sensor microcontroller configured to process local measurements and generate wake-up signals; and
galvanic isolation circuitry configured to isolate the tetrahedral electrode assembly from the controller board power supply;
a power management system configured to manage power from one or more sources comprising grid power, solar power, or battery power; and
a cable system configured to provide both power and communication between the controller board and the at least one sensor board.

2. The system of claim 1, wherein the tetrahedral electrode assembly comprises four electrodes positioned at vertices of a tetrahedron and configured to enable measurement of electrical current between different combinations of three electrodes to determine three-dimensional current flow patterns.

3. The system of claim 1, wherein the sensor microcontroller is configured to:
perform local signal processing comprising minimum and maximum calculations;
detect absolute threshold breaches; and
transmit wake-up signals to the controller board upon detecting threshold breaches.

4. The system of claim 3, wherein the local signal processing further comprises calculating the rate of change in measured current to predict hazardous conditions before threshold breaches occur.

5. The system of claim 1, wherein the power management system is configured to:
monitor grid voltage conditions;
detect grid fault conditions comprising ground voltage presence, voltage imbalance, undervoltage, and overvoltage;
automatically switch between grid power, solar power, and battery power; and
trip a ground fault circuit interrupter when dangerous current levels are detected.

6. The system of claim 1, further comprising a wherein the controller board further comprises a rechargeable battery configured to provide backup power during grid power interruptions.

7. The system of claim 1, wherein the cable system comprises one or more ruggedized cables configured to transmit power and digital communication signals over extended distances between the controller board and multiple sensor boards.

8. The system of claim 7, wherein each sensor board is configured to operate independently when data communication from the controller board is interrupted or unstable, and is configured to store local measurement data for later transmission when reconnected.

9. The system of claim 1, wherein the controller board is configured to:
coordinate ground loop potential measurements between multiple sensor boards;
display status information for each connected sensor board on the display;
receive user navigation input through the at least one button; and
execute power saving modes with wake-up capability triggered by sensor board threshold breach signals.

10. A method for detecting electrical current in water using a modular water current detection system, comprising:
initializing communication between a controller board and at least one sensor board via a digital signal network;
measuring electrical current between different combinations of three electrodes from a submerged tetrahedral electrode assembly to determine three-dimensional current flow patterns;
processing the measurements locally at the sensor board using a sensor microcontroller to detect absolute threshold breaches;
transmitting wake-up signals from the sensor board to the controller board upon detecting threshold breaches;
activating visual alerts using at least one light-emitting diode and audible alerts using a siren when dangerous current levels are detected; and
transmitting measurement data and alert information to a remote server via a communication module.

11. The method of claim 10, further comprising:
monitoring grid voltage conditions continuously when grid power is available;
detecting grid fault conditions comprising ground voltage presence, voltage imbalance, undervoltage, and overvoltage;
automatically switching between grid power, solar power, and battery power based on availability and power quality; and
tripping a ground fault circuit interrupter to disconnect grid power when dangerous current levels are detected in the water.

12. The method of claim 10, further comprising:
performing galvanic isolation between the tetrahedral electrode assembly and the controller board power supply to prevent ground loop interference;
coordinating ground loop potential measurements between multiple sensor boards when multiple sensor boards are connected to the controller board; and
applying digital signal processing filters to eliminate galvanic interference effects from the electrical current measurements.

13. The method of claim 10, further comprising:
displaying status information for each connected sensor board on a display of the controller board;
receiving user navigation input through at least one button on the controller board;
entering power saving mode at the controller board when no threshold breaches are detected; and
waking up the controller board from power saving mode upon receiving wake-up signals from the sensor board.

14. The method of claim 10, further comprising:
measuring water temperature using a temperature sensor embedded within the tetrahedral electrode assembly;
adjusting current detection thresholds based on the measured water temperature; and
transmitting environmental data comprising water temperature along with electrical current measurements to the remote server.

15. The method of claim 10, further comprising:
establishing individual ground connections for each sensor board to enable enhanced measurement modes;
performing differential calculations across multiple measurement points for improved detection accuracy; and
applying algorithmic measurement processing to distinguish between actual current leakage and environmental electrical noise.

16. The method of claim 10, further comprising:
providing power and communication to multiple sensor boards through ruggedized cables connected in a daisy-chain configuration from the controller board;
monitoring power supply status at each sensor board and reporting power conditions to the controller board; and
implementing short circuit protection for power distribution to the sensor boards.

17. A system for monitoring electrical current in a water environment, comprising:
a controller board;
one or more sensor boards positioned in the water environment, wherein the at least one sensor board has a housing selected from a floating housing or a fixed housing;
a communication link coupling the controller board to the one or more sensor boards; and
wherein the controller board is configured to receive measurement data from the one or more sensor boards and to process the measurement data to detect electrical hazards in the water environment.

18. The system of claim 17, wherein the controller board is configured to communicate with each sensor board individually and to acquire status information from each sensor board for coordinated monitoring of the water environment.

19. The system of claim 17, wherein at least one of the sensor boards comprises a local microcontroller configured to perform preliminary signal processing, generate alert signals, and relay processed measurement data to the controller board.

20. The system of claim 17, further comprising at least one extender configured to connect the controller board to at least one of the one or more sensor boards, the extender configured to relay power and data signals between the controller board and the at least one sensor board;
wherein the communication link comprises a ruggedized cable providing power and data communication, or a wireless connection operatively connecting the controller board and the at least one sensor board via the at least one extender.
